(19) United States
(12) Patent Application Publication
(10) Pub. No.: US 2026/0190347 A1
(43) Pub. Date: Jul. 2, 2026

(54) SEMICONDUCTOR DEVICE

(71) Applicant: SAMSUNG ELECTRONICS CO., LTD., Suwon-si (KR)

(72) Inventors: Kyunghwan LEE, Suwon-si (KR); Kilho LEE, Suwon-si (KR); Daewon HA, Suwon-si (KR); Jungpyo HONG, Suwon-si (KR)

(73) Assignee: SAMSUNG ELECTRONICS CO., LTD., Suwon-si (KR)

(21) Appl. No.: 19/255,147

(22) Filed: Jun. 30, 2025

(30) Foreign Application Priority Data
Dec. 31, 2024 (KR) 10-2024-0202588

(51) Int. Cl. H10B 53/30; H10B 53/10; H10B 53/20

(52) U.S. Cl. CPC H10B 53/30; H10B 53/10; H10B 53/20

(57) ABSTRACT

A semiconductor device may include a substrate, a bit line and a word line that extend in directions intersecting each other on the substrate, a semiconductor pattern connected to the bit line and adjacent to the word line, and a first data storage portion connected to the semiconductor pattern and a second data storage portion connected to the first data storage portion. The first data storage portion may include a first electrode connected to the semiconductor pattern, a second electrode surrounded by the first electrode, and a first dielectric layer disposed between the first electrode and the second electrode. The second data storage portion may include a third electrode connected to the first electrode, a fourth electrode surrounded by the third electrode, and a second dielectric layer disposed between the third electrode and the fourth electrode.

### CROSS-REFERENCE TO RELATED APPLICATION

This application claims priority to and the benefit of Korean Patent Application No. 10-2024-0202588 filed with the Korean Intellectual Property Office on Dec. 31, 2024, the entire contents of which is incorporated herein by reference.

### BACKGROUND

### 1. Field

The present disclosure relates to a semiconductor device.

### 2. Description of the Related Art

Technologies are required to increase an integration of semiconductor devices. In a case of two-dimensional semiconductor devices, an integration is mainly determined by an area occupied by a unit memory cell, and this aspect of the integration may be affected by a level of a fine pattern formation technology.

However, since the fine pattern formation technology requires expensive equipment, the integration of two-dimensional semiconductor devices is increasing but is still limited. Accordingly, 3-dimensional semiconductor memory devices having memory cells arranged 3-dimensionally are being proposed.

### SUMMARY

The present disclosure attempts to provide a semiconductor device capable of increasing the capacitance of a capacitor while minimizing an increase in the area of a unit memory cell, and implementing multi-bit operations.

A semiconductor device may include a substrate, a bit line and a word line that extend in directions intersecting each other on the substrate, a semiconductor pattern connected to the bit line and adjacent to the word line, and a first data storage portion connected to the semiconductor pattern and a second data storage portion connected to the first data storage portion. The first data storage portion may include a first electrode connected to the semiconductor pattern, a second electrode surrounded by the first electrode, and a first dielectric layer disposed between the first electrode and the second electrode. The second data storage portion may include a third electrode connected to the first electrode, a fourth electrode surrounded by the third electrode, and a second dielectric layer disposed between the third electrode and the fourth electrode.

A semiconductor device may include a substrate, a bit line and a word line that extend in directions intersecting each other on the substrate, a semiconductor pattern connected to the bit line and adjacent to the word line, and a first data storage portion connected to the semiconductor pattern and a second data storage portion connected to the first data storage portion. The first data storage portion may include a first electrode connected to the semiconductor pattern, a second electrode penetrating the first electrode and extending in a direction perpendicular to an upper surface of the substrate, and a first dielectric layer disposed between the first electrode and the second electrode. The second data storage portion may include a third electrode connected to the first electrode, a fourth electrode penetrating the third electrode and extending in the direction perpendicular to the upper surface of the substrate, and a second dielectric layer disposed between the third electrode and the fourth electrode.

A semiconductor device may include a substrate, a bit line and a word line that extend in directions intersecting each other on the substrate, a semiconductor pattern connected to the bit line and adjacent to the word line, and a plurality of data storage portions connected to the semiconductor pattern. Each of the plurality of data storage portions may include a first electrode connected to the semiconductor pattern, a second electrode surrounded by the first electrode, and a dielectric layer disposed between the first electrode and the second electrode. The first electrodes of respective ones of the plurality of data storage portions may be connected.

A method of manufacturing a semiconductor device according to an embodiment may include alternately forming a plurality of first interlayer insulating layers and a plurality of second interlayer insulating layers on a substrate, forming a first trench extending in a direction perpendicular to an upper surface of the substrate, a first hole, a second hole, and a third hole along a first direction parallel to the upper surface of the substrate by etching the plurality of first interlayer insulating layers and the plurality of second interlayer insulating layers, forming a first sacrificial layer, a second sacrificial layer, a third sacrificial layer, and a fourth sacrificial layer within the first trench, the first hole, the second hole, and the third hole, respectively, removing the second sacrificial layer located within the first hole, forming a plurality of first recesses by etching a part of the plurality of second interlayer insulating layers exposed through the first hole, forming a semiconductor pattern and a gate insulation layer within each first recess, and forming a fifth sacrificial layer within the first hole, removing the third sacrificial layer located within the second hole, forming a plurality of second recesses by etching a part of the plurality of second interlayer insulating layers exposed through the second hole, forming a first electrode and a first dielectric layer within each second recess, and forming a sixth sacrificial layer within the second hole, removing the fourth sacrificial layer located within the third hole, forming a plurality of third recesses by etching a part of the plurality of second interlayer insulating layers exposed through the third hole, forming a third electrode and a second dielectric layer within each third recess, and forming a seventh sacrificial layer within the third hole, removing the first sacrificial layer located within the first trench, forming a plurality of fourth recesses by etching a part of the plurality of second interlayer insulating layers exposed through the first trench, forming a bit line within each fourth recess, and forming third interlayer insulating layer within the first trench, and removing the fifth sacrificial layer, the sixth sacrificial layer, and the seventh sacrificial layer and forming a word line, a second electrode, and a fourth electrode within the first hole, the second hole, and the third hole, respectively.

The word line, the second electrode, and the fourth electrode may extend in the direction perpendicular to the upper surface of the substrate. The word line may be surrounded by the semiconductor pattern. The gate insulation layer may be located between the word line and the semiconductor pattern. The second electrode may be surrounded by the first electrode. The first dielectric layer may be located between the second electrode and the first electrode. The fourth electrode may be surrounded by the third electrode. The second dielectric layer may be located between the fourth electrode and the third electrode.

The forming of the semiconductor pattern and the gate insulation layer within each first recess may include forming a semiconductor material layer configured to fill the interior of the first recess within each first hole and cover side surfaces of the plurality of first interlayer insulating layers, removing a portion of the semiconductor material layer located on the side surfaces of the plurality of first interlayer insulating layers through a first etch-back process, forming a gate insulating material layer configured to fill the interior of the first recess within each first hole and the cover side surfaces of the plurality of first interlayer insulating layers, removing a portion of the gate insulating material layer located on a side surface of the plurality of first interlayer insulating layers through and a second etch-back process. A plurality of semiconductor patterns may be disposed to be spaced apart in the direction perpendicular to the upper surface of the substrate.

The forming of the first electrode and the first dielectric layer within each second recess may include forming a first electrode material layer configured to fill the interior of the second recess within each second hole and the cover side surfaces of the plurality of first interlayer insulating layers, removing a portion of the first electrode material layer located on the side surface of the plurality of first interlayer insulating layers through a third etch-back process, forming a first dielectric material layer configured to fill the interior of the second recess within each second hole and the cover side surfaces of the plurality of first interlayer insulating layers, and removing a portion of the first dielectric material layer located on the side surface of the plurality of first interlayer insulating layers through a fourth etch-back process. A plurality of first electrodes may be disposed to be spaced apart in the direction perpendicular to the upper surface of the substrate.

The forming of the third electrode and the second dielectric layer within each third recess may include forming a third electrode material layer configured to fill the interior of the third recess within each third hole and the cover side surfaces of the plurality of first interlayer insulating layers, removing a portion of the third electrode material layer located on the side surface of the plurality of first interlayer insulating layers through a fifth etch-back process, forming a second dielectric material layer configured to fill the interior of the third recess within each third hole and the cover side surfaces of the plurality of first interlayer insulating layers, and removing a portion of the second dielectric material layer located on the side surface of the plurality of first interlayer insulating layers through a sixth etch-back process. A plurality of third electrodes may be disposed to be spaced apart in the direction perpendicular to the upper surface of the substrate.

The forming of the bit line within each fourth recess may include forming a bit line material layer configured to fill the interior of the fourth recess within each first trench and the cover side surfaces of the plurality of first interlayer insulating layers, and removing a portion of the bit line material layer located on the side surface of the plurality of first interlayer insulating layers through a seventh etch-back process. A plurality of bit lines may be disposed to be spaced apart in the direction perpendicular to the upper surface of the substrate.

A part of the external circumferential surface of the semiconductor pattern may be exposed during the etching of a part of the plurality of second interlayer insulating layers exposed through the second hole. The first electrode may be formed to cover a part of the external circumferential surface of the semiconductor pattern. The first electrode may be connected to the semiconductor pattern.

A part of the external circumferential surface of the first electrode may be exposed during the etching of a part of the plurality of second interlayer insulating layers exposed through the third hole. The third electrode may be formed to cover a part of the external circumferential surface of the first electrode. The third electrode may be connected to the first electrode.

A part of the external circumferential surface of the semiconductor pattern may be exposed during the etching of a part of the plurality of second interlayer insulating layers exposed through the first trench. The bit line may be formed to cover a part of the external circumferential surface of the semiconductor pattern. The bit line may be connected to the semiconductor pattern.

A method of manufacturing a semiconductor device according to an embodiment may include, after forming the bit line, etching the plurality of second interlayer insulating layers to expose external circumferential surfaces of each first electrode and each third electrode. In the etching of the plurality of second interlayer insulating layers, a material having etch selectivity with respect to the first interlayer insulating layer, the semiconductor pattern, the first electrode, and the third electrode, and the bit line may be used.

A method of manufacturing a semiconductor device according to an embodiment may further include forming a low dielectric constant material layer on the exposed external circumferential surface of each first electrode and each third electrode.

According to an embodiment, the capacitance of a capacitor may be increased while minimizing an increase in the area of a unit memory cell of the semiconductor device, and multi-bit operations may be implemented.

### BRIEF DESCRIPTION OF THE DRAWINGS

FIG. 1 is a perspective view of a semiconductor device according to an embodiment.

FIG. 2 is a top plan view of a semiconductor device according to an embodiment.

FIG. 3 is a cross-sectional view of a semiconductor device according to an embodiment taken along line A-A′ of FIG. 2.

FIG. 4 is a cross-sectional view of a semiconductor device according to an embodiment taken along line B-B′ of FIG. 2.

Each of FIG. 5, FIG. 6, FIG. 7, FIG. 8, and FIG. 9 is a cross-sectional view correspond to a cross-section taken along line B-B′ of FIG. 2.

FIG. 10 to FIG. 12 are cross-sectional views of semiconductor devices according to various embodiments showing enlarged view of region R of FIG. 3.

FIG. 13 is a perspective view of a semiconductor device according to an embodiment.

FIG. 14 is a top plan view of a semiconductor device according to an embodiment.

FIG. 15 is a perspective view of a semiconductor device according to an embodiment.

FIG. 16 is a perspective view of a semiconductor device according to an embodiment.

FIG. 17 is a perspective view of a semiconductor device according to an embodiment.

FIG. 18 is a perspective view of a semiconductor device according to an embodiment.

FIG. 19 is a perspective view of a semiconductor device according to an embodiment.

FIG. 20 is a perspective view of a semiconductor device according to an embodiment.

FIG. 21, FIG. 23, FIG. 25, FIG. 27, FIG. 29, FIG. 31, FIG. 33, and FIG. 35 are top plan views showing a part of a manufacturing process of a semiconductor device according to an embodiment.

FIG. 22, FIG. 24, FIG. 26, FIG. 28, FIG. 30, FIG. 32, FIG. 34, and FIG. 36 are cross-sectional views showing a part of a manufacturing process of a semiconductor device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present invention, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

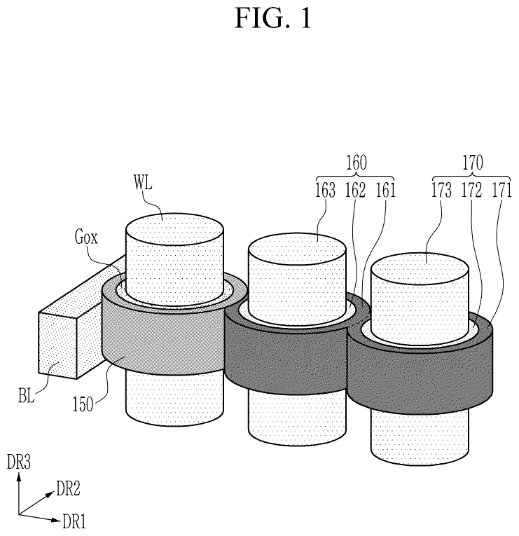

Hereinafter, a semiconductor device according to an embodiment will be described with reference to FIG. 1 to FIG. 4.

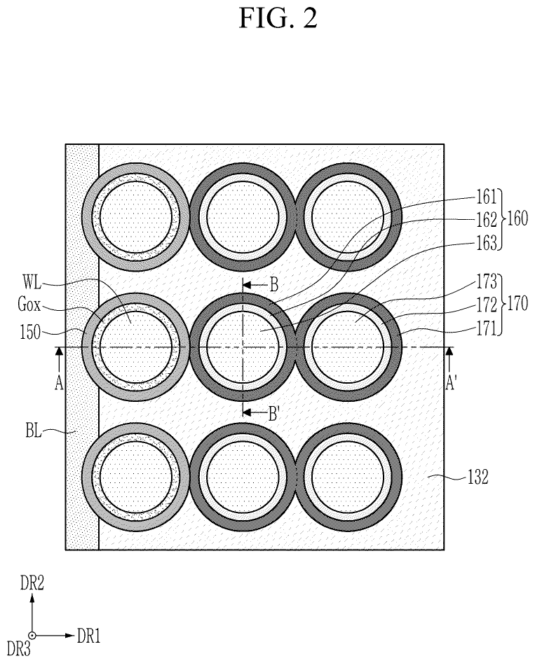

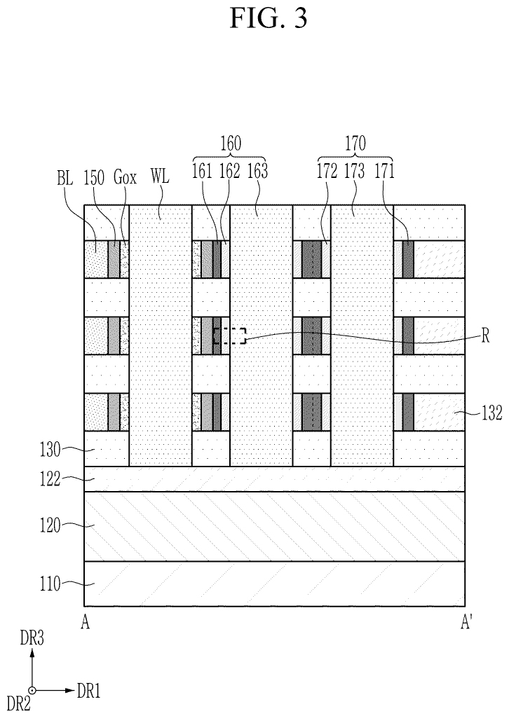

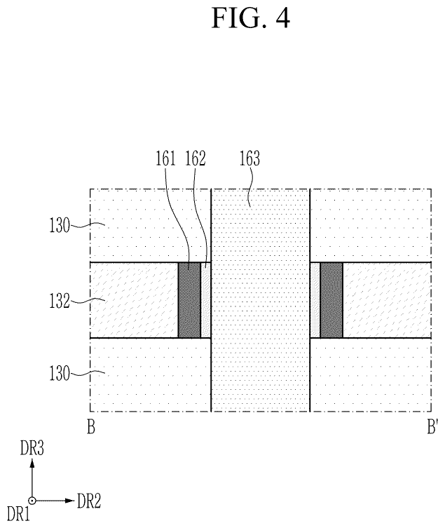

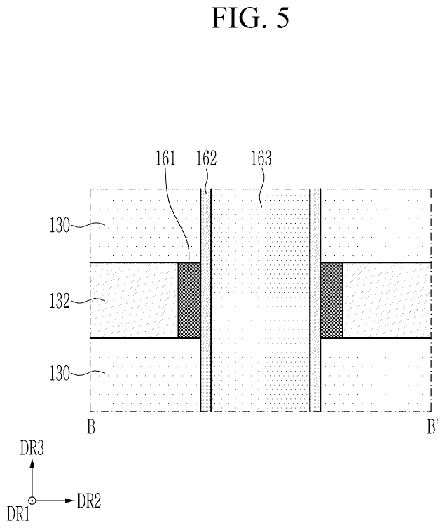

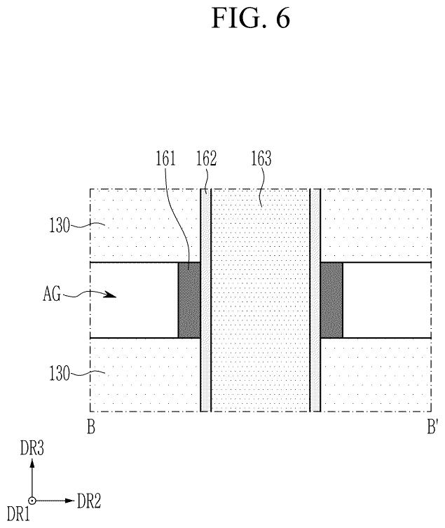

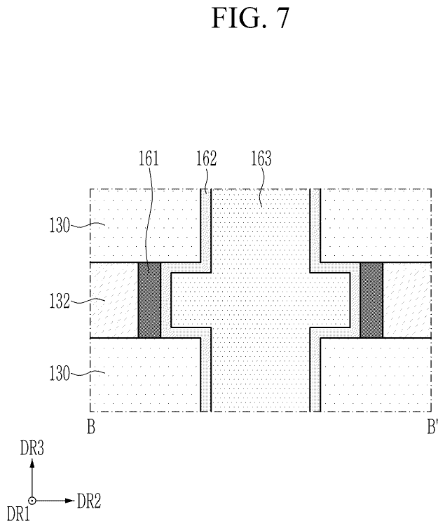

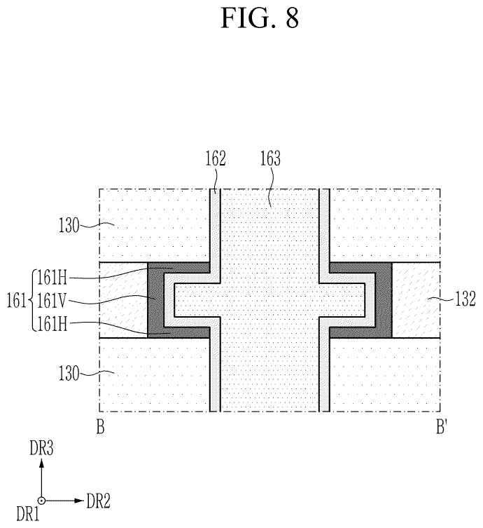

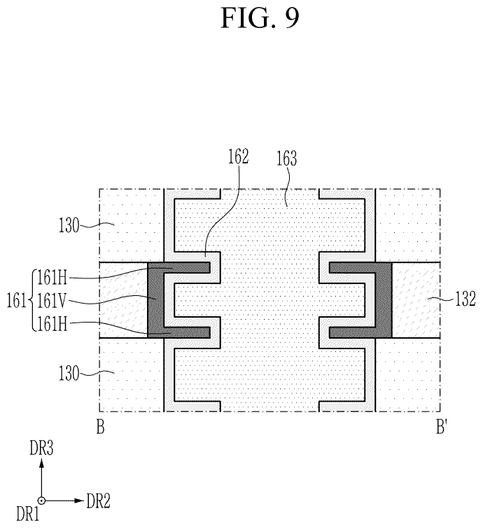

FIG. 1 is a perspective view of a semiconductor device according to an embodiment. FIG. 2 is a top plan view of a semiconductor device according to an embodiment. FIG. 3 is a cross-sectional view of a semiconductor device according to an embodiment taken along line A-A′ of FIG. 2. FIG. 4 is a cross-sectional view of a semiconductor device according to an embodiment taken along line B-B′ of FIG. 2. Merely for convenience, FIG. 1 only illustrates a bit line BL, a word line WL, a gate insulation layer Gox, a semiconductor pattern 150, and a plurality of data storage portions 160 and 170 but omits remaining components.

Referring to FIG. 1 to FIG. 4, a semiconductor device according to an embodiment may include a substrate 110, the bit line BL and the word line WL extending in directions intersecting each other on the substrate 110, the semiconductor pattern 150 connected to the bit line BL and adjacent to the word line WL, and the plurality of data storage portions 160 and 170 connected to the semiconductor pattern 150.

A semiconductor device according to an embodiment may include a plurality of memory cells. Each of the plurality of memory cells may include the semiconductor pattern 150, the bit line BL connected to the semiconductor pattern 150, the word line WL adjacent to the semiconductor pattern 150, and the plurality of data storage portions 160 and 170 connected to the semiconductor pattern 150. The plurality of memory cells may be stacked in a third direction DR3 perpendicular to an upper surface of the substrate 110. The plurality of memory cells may be arranged along a first direction DR1 and a second direction DR2 parallel to the upper surface of the substrate 110 within the same layer. That is, a semiconductor device according to an embodiment may include a plurality of memory cells that are 3-dimensionally stacked. Each of the plurality of memory cells may include one transistor and one capacitor connected to the one transistor. A semiconductor device according to an embodiment may be a dynamic random-access memory (DRAM), a ferroelectric RAM (FeRAM), or an antiferroelectric RAM (AFeRAM), depending on the material of the dielectric layer of the plurality of data storage portions 160 and 170.

The substrate 110 may include a semiconductor material. For example, the substrate 110 may include a Group IV semiconductor, a Group III-V compound semiconductor, a Group II-VI compound semiconductor, or the like. For example, the substrate 110 may include a semiconductor such as Si or Ge, or a compound semiconductor such as SiGe, SiC, GaAs, InAs, or InP. For example, the substrate 110 may be a monocrystalline epitaxial layer grown on a monocrystalline silicon substrate. However, the material of the substrate 110 is not limited thereto, and may be variously modified.

A first insulation layer 120 may be located on the substrate 110. The first insulation layer 120 may be located on the upper surface of the substrate 110. The first insulation layer 120 may cover the upper surface of the substrate 110.

The first insulation layer 120 may include an insulating material. For example, the first insulation layer 120 may include silicon oxide, silicon nitride, silicon oxynitride, or a combination thereof, but is not limited thereto. By the first insulation layer 120, a second electrode 163 and a fourth electrode 173 described later may be insulated from the substrate 110. By the first insulation layer 120, the word line WL described later may be insulated from the substrate 110.

A second insulation layer 122 may be located on the first insulation layer 120. The second insulation layer 122 may be located on an upper surface of the first insulation layer 120. The second insulation layer 122 may be used as an etch-stop layer in the process of etching a first interlayer insulating layer 130 and a second interlayer insulating layer 132 described later. The second insulation layer 122 may include a material having etch selectivity with respect to the first interlayer insulating layer 130 and the second interlayer insulating layer 132.

The second insulation layer 122 may include an insulating material. For example, the second insulation layer 122 may include silicon oxide, silicon nitride, silicon oxynitride, or a combination thereof, but is not limited thereto.

The word line WL, the bit line BL, the semiconductor pattern 150, and the plurality of data storage portions 160 and 170 may be located on the second insulation layer 122. The word line WL may extend in a direction intersecting the bit line BL. For example, the word line WL may extend in the direction perpendicular to an elongation direction of the bit line BL. In an embodiment, the word line WL may extend in a direction (e.g., the third direction DR3) perpendicular to the upper surface of the substrate 110. The word line WL may have a pillar shape. A planar shape of the word line WL may be circular, but is not limited thereto. For example, the planar shape of the word line WL may be variously modified to an elliptical shape, a rectangular shape, or the like.

In an embodiment, the semiconductor device may include a plurality of word lines WL. The plurality of word lines WL may be disposed to be spaced apart along the second direction DR2 on a side of the bit line BL. Although not shown in the drawings, the plurality of word lines WL may be further disposed to be spaced apart along the first direction DR1.

The word line WL may be adjacent to the semiconductor pattern 150. In an embodiment, the word line WL may penetrate the semiconductor pattern 150 in the third direction DR3. An external circumferential surface of the word line WL may be adjacent to an inner surface of the semiconductor pattern 150. However, the embodiment is not limited thereto, and the word line WL may not penetrate the semiconductor pattern 150.

A semiconductor device according to an embodiment may include the gate insulation layer Gox located between the word line WL and the semiconductor pattern 150. By the gate insulation layer Gox, the word line WL may be spaced apart from the semiconductor pattern 150.

The word line WL may include a conductive material. The word line WL may include, for example, a doped semiconductor material, a conductive metal nitride, a metal, a metal-semiconductor compound, or a combination thereof, but is not limited thereto.

The gate insulation layer Gox may include at least one among a high-dielectric material, a silicon oxide, a silicon nitride, or a silicon oxynitride. The high-dielectric material may include, for example, at least one among hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In an embodiment, the semiconductor pattern 150 may surround the word line WL. The semiconductor pattern 150 may surround the external circumferential surface of the word line WL. In this case, the semiconductor pattern 150 may not surround the entire external circumferential surface of the word line WL. For example, the semiconductor pattern 150 may surround a region overlapping with the bit line BL among the external circumferential surface of the word line WL and a region adjacent thereto.

For example, the word line WL may have a pillar shape, and the semiconductor pattern 150 may have a ring shape. For example, the word line WL may have a cylindrical shape, and the semiconductor pattern 150 may have a circular ring shape.

In an embodiment, the semiconductor device may include a plurality of semiconductor patterns 150. The plurality of semiconductor patterns 150 may be disposed to be spaced apart along the second direction DR2 on a side of the bit line BL. Although not shown in the drawings, the plurality of semiconductor patterns 150 may be further disposed to be spaced apart along the first direction DR1. The plurality of semiconductor patterns 150 may be stacked in the third direction DR3 perpendicular to the upper surface of the substrate 110. In an embodiment, the plurality of semiconductor patterns 150 stacked in the third direction DR3 may surround a single word line WL extending in the third direction DR3. The plurality of semiconductor patterns 150 surrounding the single word line WL may be disposed to be spaced apart along the third direction DR3.

A semiconductor device according to an embodiment may include the first interlayer insulating layer 130 located between the plurality of semiconductor patterns 150 disposed spaced apart along the third direction DR3, and the second interlayer insulating layer 132 located between the plurality of semiconductor patterns 150 disposed spaced apart along the first direction DR1 and the second direction DR2. A semiconductor device according to an embodiment may include a plurality of first interlayer insulating layers 130 and a plurality of second interlayer insulating layers 132, and the plurality of first interlayer insulating layers 130 and the plurality of second interlayer insulating layers 132 may be alternately stacked on the second insulation layer 122 in the third direction DR3 perpendicular to the upper surface of the substrate 110. The word line WL and the second electrode 163 and the fourth electrode 173 described later may penetrate the plurality of first interlayer insulating layers 130 and the plurality of second interlayer insulating layers 132 stacked in the third direction DR3.

The first interlayer insulating layer 130 and the second interlayer insulating layer 132 may include an insulating material. In an embodiment, the first interlayer insulating layer 130 and the second interlayer insulating layer 132 may include a material having etch selectivity with respect to the second insulation layer 122. For example, each of the first interlayer insulating layer 130 and the second interlayer insulating layer 132 may include, silicon oxide, or silicon nitride, but is not limited thereto. In an embodiment, the second interlayer insulating layer 132 may include a material having etch selectivity with respect to the first interlayer insulating layer 130. In an embodiment, the second interlayer insulating layer 132 may include a low dielectric constant material, but is not limited thereto.

In an embodiment, the second interlayer insulating layer 132 may be located in the same layer as the semiconductor pattern 150, a first electrode 161, and a third electrode 171 described later. The second interlayer insulating layer 132 may surround a side surface of each of the semiconductor pattern 150, the first electrode 161, and the third electrode 171. In an embodiment, at least a portion of the second interlayer insulating layer 132 may be removed. For example, a portion of the second interlayer insulating layer 132 surrounding side surfaces of the first electrode 161 and the third electrode 171 may be removed, and accordingly, an air gap may be located on the side surfaces of the first electrode 161 and the third electrode 171.

In an embodiment, the semiconductor pattern 150 may include a semiconductor material. For example, the semiconductor pattern 150 may include silicon, germanium, or silicon-germanium. For example, the semiconductor pattern 150 may include monocrystalline silicon or polycrystalline silicon. However, the embodiment is not limited thereto. For example, the semiconductor pattern 150 may include an oxide semiconductor material such as indium gallium zinc oxide (IGZO). As another example, the semiconductor pattern 150 may include a 2-dimension semiconductor material such as molybdenum disulfide (MoS2).

In an embodiment, the semiconductor pattern 150 may include a channel region. The channel region may be located between a portion of the semiconductor pattern 150 connected to the bit line BL and a portion of the semiconductor pattern 150 connected to a first data storage portion 160. The channel region may surround the word line WL. A semiconductor device according to an embodiment may have a channel-all-around (CAA) structure in which the channel region of the semiconductor pattern 150 surrounds the word line WL.

In an embodiment, the bit line BL may extend in a direction intersecting the word line WL. The bit line BL may extend in a direction (e.g., the second direction DR2) parallel to the upper surface of the substrate 110. For example, the bit line BL may have a rod shape extending in the second direction DR2.

In an embodiment, the bit line BL may be connected to the semiconductor pattern 150. The bit line BL may be connected to the semiconductor pattern 150 in a direction intersecting the elongation direction of the bit line BL. For example, the bit line BL may be connected to the semiconductor pattern 150 in the direction perpendicular to the elongation direction of the bit line BL. For example, the bit line BL may extend in the second direction DR2, and the bit line BL may be connected to the semiconductor pattern 150 in the first direction DR1 perpendicular to the second direction DR2.

In an embodiment, one surface of the bit line BL along the first direction DR1 may be in contact with the semiconductor pattern 150, but is not limited thereto. For example, another predetermined layer (e.g., silicide layer) may be further located between the bit line BL and the semiconductor pattern 150. In an embodiment, a part of the semiconductor pattern 150 adjacent to the bit line BL may be covered with the bit line BL. A part of the semiconductor pattern 150 may be buried in the bit line BL in the first direction DR1. The bit line BL may cover a part of an external circumferential surface of the semiconductor pattern 150 and extend in the second direction DR2. The bit line BL may overlap with a part of the semiconductor pattern 150 in the second direction DR2. The bit line BL may be in contact with a part of the external circumferential surface of the semiconductor pattern 150. For example, since the external circumferential surface of the semiconductor pattern 150 is a curved surface, one surface of the bit line BL along the first direction DR1 in contact with the external circumferential surface of the semiconductor pattern 150 may include a curved surface.

In an embodiment, semiconductor device may include a plurality of bit lines BL. The plurality of bit lines BL may be stacked in the third direction DR3 perpendicular to the upper surface of the substrate 110. In an embodiment, each of the plurality of bit lines BL stacked in the third direction DR3 may be connected to the plurality of semiconductor patterns 150 disposed to be spaced apart along the second direction DR2. Although not shown in the drawings, the plurality of bit lines BL may be further disposed to be spaced apart along the first direction DR1. For example, the semiconductor pattern 150, the word line WL, and the plurality of data storage portions 160 and 170 may have a symmetrical structure based on two bit lines BL adjacent in the first direction DR1, but are not limited thereto. For example, the semiconductor pattern 150 shown in FIG. 1 to FIG. 4, the word line WL penetrating the semiconductor pattern 150, the bit line BL connected to a first side of the semiconductor pattern 150, and the plurality of data storage portions 160 and 170 connected to a second side of the semiconductor pattern 150 may be repeatedly disposed along the first direction DR1.

The bit line BL may include a conductive material. The bit line BL may include, for example, a doped semiconductor material, a conductive metal nitride, a metal, a metal-semiconductor compound, or a combination thereof, but is not limited thereto.

In an embodiment, the plurality of data storage portions 160 and 170 connected to one semiconductor pattern 150 may include the first data storage portion 160 and second data storage portion 170. The first data storage portion 160 may be connected to the semiconductor pattern 150, and the second data storage portion 170 may be connected to the first data storage portion 160.

In an embodiment, the first data storage portion 160 may include the first electrode 161 connected to the semiconductor pattern 150, the second electrode 163 surrounded by the first electrode 161, a first dielectric layer 162 located between the first electrode 161 and the second electrode 163. The second data storage portion 170 may include the third electrode 171 connected to the first electrode 161, the fourth electrode 173 surrounded by the third electrode 171, and a second dielectric layer 172 located between the third electrode 171 and the fourth electrode 173. Each of the first data storage portion 160 and the second data storage portion 170 includes two electrodes and a dielectric layer located between the two electrodes, and may be referred to as a capacitor. The first electrode 161 of the first data storage portion 160 and the third electrode 171 of the second data storage portion 170 are connected, and therefore, the first data storage portion 160 and the second data storage portion 170 may be used as one capacitor.

In an embodiment, the first electrode 161 may be connected to the semiconductor pattern 150 in the first direction DR1. A part of the semiconductor pattern 150 adjacent to the first electrode 161 may be covered with the first electrode 161. A part of the semiconductor pattern 150 may be buried in the first electrode 161 in the first direction DR1. The first electrode 161 may overlap with a part of the semiconductor pattern 150 in the second direction DR2. The first electrode 161 may cover a part of the external circumferential surface of the semiconductor pattern 150.

In an embodiment, the first electrode 161 may be in contact with the semiconductor pattern 150, but is not limited thereto. For example, another predetermined layer may be further located between the first electrode 161 and the semiconductor pattern 150. The first electrode 161 may be in contact with a part of the external circumferential surface of the semiconductor pattern 150. For example, since the external circumferential surface of the semiconductor pattern 150 is a curved surface, the surface of the first electrode 161 in contact with the external circumferential surface of the semiconductor pattern 150 may include a curved surface.

The bit line BL may be connected to a first side of the semiconductor pattern 150 according to the first direction DR1, and the first electrode 161 may be connected to a second side of the semiconductor pattern 150 according to the first direction DR1.

In an embodiment, the first electrode 161 may surround the second electrode 163. The first electrode 161 may surround an external circumferential surface of the second electrode 163. In this case, the first electrode 161 may not surround the entire external circumferential surface of the second electrode 163. For example, the first electrode 161 may surround a region overlapping with the semiconductor pattern 150 in the first direction DR1 among the external circumferential surface of the second electrode 163.

According to what was described above, the first electrode 161 of each of the plurality of memory cells may be disposed to be spaced apart in the third direction DR3. The first electrode 161 of a certain memory cell may surround a part of the external circumferential surface of the second electrode 163. The first electrode 161 of another memory cell spaced apart in the third direction DR3 may surround another part of the external circumferential surface of the second electrode 163. The first interlayer insulating layer 130 may be located between the first electrodes 161 spaced apart in the third direction DR3. Still another part of the second electrode 163 may be surrounded by the first interlayer insulating layer 130.

In an embodiment, the second electrode 163 may extend in the third direction DR3 perpendicular to the upper surface of the substrate 110. The second electrode 163 may extend in the third direction DR3 within a space surrounded by the first electrode 161. The second electrode 163 may penetrate the first electrode 161 in the third direction DR3.

For example, the second electrode 163 may have a pillar shape, and the first electrode 161 may have a ring shape. For example, the second electrode 163 may have a cylindrical shape, and the first electrode 161 may have a circular ring shape. A planar shape of the first electrode 161 and the second electrode 163 may be circular, but is not limited thereto. For example, the planar shape of the first electrode 161 and the second electrode 163 may be variously modified to an elliptical shape, a rectangular shape, or the like.

In an embodiment, the plurality of first interlayer insulating layers 130 may be located on an upper surface of the first electrode 161 and a lower surface of the first electrode 161. The first electrode 161 may be located between two first interlayer insulating layers 130 adjacent in the third direction DR3. Not only a first electrode 161 but also the semiconductor pattern 150 may be located between the two first interlayer insulating layers 130 adjacent in the third direction DR3.

The first electrode 161 may be covered with the second interlayer insulating layer 132. In an embodiment, an external circumferential surface of the first electrode 161 may be covered with the second interlayer insulating layer 132. Although not shown in the drawings, not only the first electrode 161 but also the external circumferential surface of the semiconductor pattern 150 may be covered with the second interlayer insulating layer 132. In an embodiment, a part of the external circumferential surface of the semiconductor pattern 150 that is not covered with the bit line BL and the first electrode 161, and the external circumferential surface of a part of the first electrode 161 that is not covered with the semiconductor pattern 150 and the third electrode 171 may be covered with the second interlayer insulating layer 132.

Referring to FIG. 3 and FIG. 4, on a cross-section according to the second direction DR2 and the third direction DR3, the second electrode 163 may linearly extend on an inner surface of the first electrode 161 and inner surfaces of the plurality of first interlayer insulating layers 130. The second electrode 163 may linearly extend on the inner surfaces of the plurality of first interlayer insulating layers 130 located on the inner surface of the first electrode 161 and both sides of the first electrode 161 along the third direction DR3. That the second electrode 163 linearly extends may mean that the width (e.g., diameter) of the second electrode 163 is constant along an elongation direction of the second electrode 163.

By the first dielectric layer 162, the first electrode 161 and the second electrode 163 may be spaced apart. In an embodiment, the first dielectric layer 162 may be located on the inner surface of the first electrode 161. The first dielectric layer 162 may be located on the external circumferential surface of the second electrode 163. In an embodiment, the first dielectric layer 162 may surround the second electrode 163 on an inner side of the first electrode 161. The first dielectric layer 162 may have a ring shape.

In an embodiment, the plurality of first interlayer insulating layers 130 may be located on an upper surface of the first dielectric layer 162 and a lower surface of the first dielectric layer 162. The first dielectric layer 162 may be located between the two first interlayer insulating layers 130 adjacent in the third direction DR3.

In an embodiment, a length of the first dielectric layer 162 along the third direction DR3 may be substantially the same as a length of the first electrode 161 along the third direction DR3, but is not limited thereto. For example, the length of the first dielectric layer 162 along the third direction DR3 may be longer than the length of the first electrode 161 along the third direction DR3. For example, the first dielectric layer 162 may extend in the third direction DR3 along the external circumferential surface of the second electrode 163.

The first electrode 161, the first dielectric layer 162, and the second electrode 163 may have the same central axis. The first dielectric layer 162 may have a thickness in a diameter direction centered on a central axis of the first electrode 161, the first dielectric layer 162, and the second electrode 163. The thickness of the first dielectric layer 162 may mean a distance between the first electrode 161 and the second electrode 163. A distance between the first electrode 161 and the second electrode 163 may mean a distance between the inner surface of the first electrode 161 and the external circumferential surface of the second electrode 163.

The first electrode 161 and the second electrode 163 may include a conductive material. Each of the first electrode 161 and the second electrode 163 may include, for example, at least one among a metallic material, a conductive metal nitride, and a doped semiconductor material. The first dielectric layer 162 may include at least one among a high-dielectric material, a ferroelectric material, or an antiferroelectric material.

In an embodiment, the first electrode 161 and the second electrode 163 may include the same material, but are not limited thereto. For example, the first electrode 161 and the second electrode 163 may include different materials. For example, the first electrode 161 and the second electrode 163 may include materials having different work functions. When the first electrode 161 and the second electrode 163 include materials having different work functions, and the first dielectric layer 162 includes a ferroelectric material, the hysteresis curve of the first dielectric layer 162 may be shifted. In this case, a write voltage and a read voltage of a ferroelectric memory including the first data storage portion 160 may be set to be different, and the read voltage may be lowered.

In an embodiment, the third electrode 171 may be connected to the first electrode 161 in the first direction DR1. A part of the first electrode 161 adjacent to the third electrode 171 may be covered with the third electrode 171. A part of the first electrode 161 may be buried in the third electrode 171 in the first direction DR1. The third electrode 171 may overlap with a part of the first electrode 161 in the second direction DR2. The third electrode 171 may cover a part of the external circumferential surface of the first electrode 161.

In an embodiment, the third electrode 171 may be in contact with the first electrode 161. The third electrode 171 may be in contact with a part of the external circumferential surface of the first electrode 161. For example, since the external circumferential surface of the first electrode 161 is a curved surface, a surface of the third electrode 171 in contact with the external circumferential surface of the first electrode 161 may include a curved surface.

In an embodiment, the third electrode 171 may include the same material as the first electrode 161. In this case, the third electrode 171 may be integrally formed with the first electrode 161. However, the embodiment is not limited thereto. For example, the third electrode 171 may include a different material from the first electrode 161.

The semiconductor pattern 150 may be connected to a first side of the first electrode 161 according to the first direction DR1, and the third electrode 171 may be connected to a second side of the first electrode 161 according to the first direction DR1.

In an embodiment, the third electrode 171 may surround the fourth electrode 173. The third electrode 171 may surround an external circumferential surface of the fourth electrode 173. In this case, the third electrode 171 may not surround the entire external circumferential surface of the fourth electrode 173. For example, the third electrode 171 may surround a region overlapping with the third electrode 171 in the first direction DR1 among the external circumferential surface of the fourth electrode 173.

In an embodiment, the fourth electrode 173 may extend in the third direction DR3 perpendicular to the upper surface of the substrate 110. The fourth electrode 173 may extend in the third direction DR3 within a space surrounded by the third electrode 171. The fourth electrode 173 may penetrate the third electrode 171 in the third direction DR3.

For example, the fourth electrode 173 may have a pillar shape, and the third electrode 171 may have a ring shape. For example, the fourth electrode 173 may have a cylindrical shape, and the third electrode 171 may have a circular ring shape. A planar shape of the third electrode 171 and the fourth electrode 173 may be circular, but is not limited thereto. For example, the planar shape of the third electrode 171 and the fourth electrode 173 may be variously modified to an elliptical shape, a rectangular shape, or the like.

In an embodiment, the plurality of first interlayer insulating layers 130 may be located on an upper surface of the third electrode 171 and a lower surface of the third electrode 171. The third electrode 171 may be located between the two first interlayer insulating layers 130 adjacent in the third direction DR3.

The third electrode 171 may be covered with the second interlayer insulating layer 132. In an embodiment, an external circumferential surface of the third electrode 171 may be covered with the second interlayer insulating layer 132. In an embodiment, a part of the external circumferential surface of the third electrode 171 that is not covered with the first electrode 161 may be covered with the second interlayer insulating layer 132.

Referring to FIG. 4, on the cross-section according to the second direction DR2 and the third direction DR3, the fourth electrode 173 may linearly extend on an inner surface of the third electrode 171 and the inner surfaces of the plurality of first interlayer insulating layers 130. The fourth electrode 173 may linearly extend on the inner surfaces of the plurality of first interlayer insulating layers 130 located on the inner surface of the third electrode 171 and both sides of the third electrode 171 along the third direction DR3. That the fourth electrode 173 linearly extends may mean that the width (e.g., diameter) of the fourth electrode 173 is constant along an elongation direction of the fourth electrode 173.

By the second dielectric layer 172, the third electrode 171 and the fourth electrode 173 may be spaced apart. In an embodiment, the second dielectric layer 172 may be located on the inner surface of the third electrode 171. The second dielectric layer 172 may be located on the external circumferential surface of the fourth electrode 173. In an embodiment, the second dielectric layer 172 may surround the fourth electrode 173 on an inner side of the third electrode 171. The second dielectric layer 172 may have a ring shape.

In an embodiment, the plurality of first interlayer insulating layers 130 may be located on an upper surface of the second dielectric layer 172 and a lower surface of the second dielectric layer 172. The second dielectric layer 172 may be located between the two first interlayer insulating layers 130 adjacent in the third direction DR3.

In an embodiment, a length of the second dielectric layer 172 along the third direction DR3 may be substantially the same as a length of the third electrode 171 along the third direction DR3, but is not limited thereto. For example, the length of the second dielectric layer 172 along the third direction DR3 may be longer than the length of the third electrode 171 along the third direction DR3. For example, the second dielectric layer 172 may extend in the third direction DR3 along the external circumferential surface of the fourth electrode 173.

The third electrode 171, the second dielectric layer 172, and the fourth electrode 173 may have the same central axis. The second dielectric layer 172 may have a thickness in a diameter direction centered on a central axis of the third electrode 171, the second dielectric layer 172, and the fourth electrode 173. The thickness of the second dielectric layer 172 may mean a distance between the third electrode 171 and the fourth electrode 173. A distance between the third electrode 171 and the fourth electrode 173 may mean a distance between the inner surface of the third electrode 171 and the external circumferential surface of the fourth electrode 173.

The third electrode 171 and the fourth electrode 173 may include a conductive material. Each of the third electrode 171 and the fourth electrode 173 may include, for example, at least one among a metallic material, a conductive metal nitride, and a doped semiconductor material. The second dielectric layer 172 may include at least one among a high-dielectric material, a ferroelectric material, or an antiferroelectric material.

In an embodiment, the third electrode 171 may include the same material as the first electrode 161, but is not limited thereto. For example, the third electrode 171 may include a different material from the first electrode 161. In an embodiment, the fourth electrode 173 may include the same material as the second electrode 163, but is not limited thereto. For example, the fourth electrode 173 may include a different material from the second electrode 163.

In an embodiment, the third electrode 171 and the fourth electrode 173 may include the same material, but is not limited thereto. For example, the third electrode 171 and the fourth electrode 173 may include different materials. For example, the third electrode 171 and the fourth electrode 173 may include materials having different work functions. When the third electrode 171 and the fourth electrode 173 include materials having different work functions, and the second dielectric layer 172 includes a ferroelectric material, the hysteresis curve of the second dielectric layer 172 may be shifted. In this case, a write voltage and a read voltage of a ferroelectric memory including the second data storage portion 170 may be set to be different, and the read voltage may be lowered.

In an embodiment, voltages may be independently applied the second electrode 163 and the fourth electrode 173. For example, the voltage may be applied to the second electrode 163 and the fourth electrode 173 at different timings, and voltages of different magnitudes may be applied to the second electrode 163 and the fourth electrode 173.

In an embodiment, different information may be stored in the first data storage portion 160 and the second data storage portion 170. For example, different voltage may be applied in the second electrode 163 and the fourth electrode 173. As another example, at least one of the thickness, remanent polarization Pᵣ, or area of the first dielectric layer 162 and the second dielectric layer 172 may be different. Thicknesses of the first dielectric layer 162 and the second dielectric layer 172 may mean a thickness in a diameter direction centered on a central axis of each of the first dielectric layer 162 and the second dielectric layer 172. The remanent polarization Pᵣ of the first dielectric layer 162 and the second dielectric layer 172 may be determined according to the ferroelectric material included in each of the first dielectric layer 162 and the second dielectric layer 172. An area of the first dielectric layer 162 and the second dielectric layer 172 may mean an area in which the first electrode 161 and the third electrode 171 overlaps with the second electrode 163 and the fourth electrode 173, respectively. For example, the area of the first dielectric layer 162 and the second dielectric layer 172 may be determined according to inner diameters of the first electrode 161 and the third electrode 171 and the lengths of the first electrode 161 and the third electrode 171 along the third direction DR3.

In an embodiment, since the first data storage portion 160 and the second data storage portion 170 may store different information, one memory cell including the first data storage portion 160 and the second data storage portion 170 may store at least two bits of data. However, the embodiment is not limited thereto. For example, one memory cell including the first data storage portion 160 and the second data storage portion 170 may store one bit of data. In this case, the capacitance of the capacitor may be increased compared to a memory cell including only one data storage portion (e.g., a memory cell including only the first data storage portion 160).

In an embodiment, semiconductor device may include a plurality of first data storage portion 160 connected to the plurality of semiconductor patterns 150, respectively, and a plurality of second data storage portions 170 connected to the plurality of first data storage portion 160, respectively. The plurality of first data storage portion 160 may be disposed to be spaced apart along the second direction DR2. Although not shown in the drawings, the plurality of first data storage portion 160 may be further disposed to be spaced apart along the first direction DR1. The plurality of first data storage portion 160 may be stacked along the third direction DR3.

In an embodiment, the plurality of first data storage portion 160 stacked along the third direction DR3 may include a plurality of first electrodes 161 disposed spaced apart along the third direction DR3, a single second electrode 163 extending in the third direction DR3 to penetrate the plurality of first electrodes 161, and a plurality of first dielectric layers 162 located between each of the plurality of first electrodes 161 and the single second electrode 163. However, the embodiment is not limited thereto. For example, a single first dielectric layer 162 may be located between each of the plurality of first electrodes 161 and the single second electrode 163 disposed to be spaced apart along the third direction DR3.

The plurality of second data storage portions 170 may be disposed to be spaced apart along the second direction DR2. Although not shown in the drawings, the plurality of second data storage portions 170 may be further disposed to be spaced apart along the first direction DR1. The plurality of second data storage portions 170 may be stacked along the third direction DR3.

In an embodiment, the plurality of second data storage portions 170 stacked along the third direction DR3 may include a plurality of third electrodes 171 disposed spaced apart along the third direction DR3, a single fourth electrode 173 extending in the third direction DR3 to penetrate the plurality of third electrodes 171, and a plurality of second dielectric layers 172 located between each of the plurality of third electrodes 171 and the single fourth electrode 173. However, the embodiment is not limited thereto. For example, a single second dielectric layer 172 may be located between each of the plurality of third electrodes 171 and the single fourth electrode 173 disposed to be spaced apart along the third direction DR3.

In the embodiment shown in FIG. 1 to FIG. 4, the number of data storage portions 160 and 170 connected to one semiconductor pattern 150 is illustrated as two, but is not limited thereto. For example, the number of data storage portions connected to one semiconductor pattern 150 may be three or more.

A semiconductor device according to an embodiment may include the plurality of data storage portions 160 and 170 connected to one semiconductor pattern 150. Each of the plurality of data storage portions 160 and 170 may include the two electrodes and a dielectric layer located between the two electrodes. They may have a structure in which one electrode among the two electrodes penetrates another electrode and extends in a direction perpendicular to the upper surface of the substrate 110. In Comparative Example in which the two electrodes of the data storage portions extend in the direction parallel to the upper surface of the substrate 110, in order to connect the electrodes of the data storage portion to an upper wire or a lower wire, an electrode extending in the direction perpendicular to the upper surface of the substrate 110 may be further included. According to an embodiment, an additional region to connect the data storage portion to wires is not required, thereby preventing an increase of the area occupied by a unit cell. In addition, even if the number of data storage portions increases, an increase of the area occupied by the unit cell may be reduced. In addition, the difficulty of the manufacturing process may be lowered in terms of step coverage. According to an embodiment, the capacitance of the capacitor per unit volume may increase. Alternatively, a semiconductor device according to an embodiment may store multiple bits.

Hereinafter, various modifications of a data storage portion of a semiconductor device according to an embodiment shown in FIG. 1 to FIG. 4 will be described with reference to FIG. 5 to FIG. 9.

Each of FIG. 5, FIG. 6, FIG. 7, FIG. 8, and FIG. 9 is a cross-sectional view correspond to a cross-section taken along line B-B′ of FIG. 2. The embodiment shown in each of FIG. 5, FIG. 6, FIG. 7, FIG. 8, and FIG. 9 may be significantly the same as the embodiment shown in FIG. 1 to FIG. 4. In the embodiment shown in each of FIG. 5, the same components as FIG. 6, FIG. 7, FIG. 8, and FIG. 9, the embodiment shown in FIG. 1 to FIG. 4 may be referred to with the same reference numerals. Hereinafter, regarding the embodiment shown in each of FIG. 5, FIG. 6, FIG. 7, FIG. 8, and FIG. 9, differences from the previous embodiments will be mainly described. The embodiment shown in each of FIG. 5, FIG. 6, FIG. 7, FIG. 8, and FIG. 9 may be partially different from the previous embodiment in the structure of the first interlayer insulating layer 130 and the second interlayer insulating layer 132 surrounding the first data storage portion 160, and the first data storage portion 160. Meanwhile, the description of a structure of the first interlayer insulating layer 130 and the second interlayer insulating layer 132 surrounding the first data storage portion 160 described later and the first data storage portion 160 may be equally applied to the first interlayer insulating layer 130 and the second interlayer insulating layer 132 surrounding the second data storage portion 170, and the second data storage portion 170.

Referring to FIG. 5, unlike the embodiment shown in FIG. 1 to FIG. 4, the first dielectric layer 162 may cover the inner surfaces of the plurality of first interlayer insulating layers 130 located on the inner surface of the first electrode 161 and the both sides of the first electrode 161 along the third direction DR3 and may extend in the third direction DR3. In an embodiment, the first electrode 161 may be located between the two first interlayer insulating layers 130 adjacent in the third direction DR3, but the first dielectric layer 162 may not be located between the two first interlayer insulating layers 130 adjacent in the third direction DR3. In the embodiment shown in FIG. 5, the first dielectric layer 162 may not only cover the inner surface of the first electrode 161, but may further cover an inner surface of the first interlayer insulating layer 130. The first dielectric layer 162 may be further located not only between the inner surface of the first electrode 161 and the external circumferential surface of the second electrode 163 but also between the inner surface of the first interlayer insulating layer 130 and the external circumferential surface of the second electrode 163. The first dielectric layer 162 may cover the entire external circumferential surface of the second electrode 163.

In an embodiment, the single first dielectric layer 162 may be located between the plurality of first electrodes 161 and the single second electrode 163. The plurality of first electrodes 161 disposed to be spaced apart in the third direction DR3 may be covered with the single first dielectric layer 162.

In an embodiment, width (e.g., diameter) of the first dielectric layer 162 may be constant along the third direction DR3 in which the first dielectric layer 162 extends.

Referring to FIG. 6, as in the embodiment shown in FIG. 5, the first dielectric layer 162 may cover the inner surfaces of the plurality of first interlayer insulating layers 130 located on the inner surface of the first electrode 161 and the both sides of the first electrode 161 along the third direction DR3 and may extend in the third direction DR3. The first dielectric layer 162 may be further located not only between the inner surface of the first electrode 161 and the external circumferential surface of the second electrode 163 but also between the inner surface of the first interlayer insulating layer 130 and the external circumferential surface of the second electrode 163. The first dielectric layer 162 may cover the entire external circumferential surface of the second electrode 163. The single first dielectric layer 162 may cover inner surfaces of the plurality of first electrodes 161 disposed spaced apart in the third direction DR3.

In the embodiment shown in FIG. 6, unlike the embodiment shown in FIG. 5, the second interlayer insulating layer 132 surrounding the external circumferential surface of the first electrode 161 may be omitted. In an embodiment, an air gap AG may be located on the external circumferential surface of the first electrode 161.

Referring to FIG. 7, as in the embodiment shown in FIG. 5, the first dielectric layer 162 may cover the inner surfaces of the plurality of first interlayer insulating layers 130 located on the inner surface of the first electrode 161 and the both sides of the first electrode 161 along the third direction DR3. The first dielectric layer 162 may be further located not only between the inner surface of the first electrode 161 and the external circumferential surface of the second electrode 163 but also between the inner surface of the first interlayer insulating layer 130 and the external circumferential surface of the second electrode 163. The first dielectric layer 162 may cover the entire external circumferential surface of the second electrode 163. The single first dielectric layer 162 may cover inner surfaces of the plurality of first electrodes 161 disposed spaced apart in the third direction DR3.

In the embodiment shown in FIG. 7, unlike the embodiment shown in FIG. 5, the first dielectric layer 162 may further cover a part of surfaces facing in the third direction DR3 between the plurality of first interlayer insulating layers 130 stacked in the third direction DR3. That is, the first dielectric layer 162 may further cover a part of the upper surface and the lower surface of each of the plurality of first interlayer insulating layers 130.

In an embodiment, the second electrode 163 may be not only located within a space surrounded by the inner surface of the first electrode 161 and the inner surface of the first interlayer insulating layer 130, but also further located between the plurality of first interlayer insulating layers 130 located on the both sides of the first electrode 161 along the third direction DR3. The second electrode 163 may include a portion protruding in a diameter direction from an external circumferential surface of a portion extending in the third direction DR3 toward the inner surface of the first electrode 161.

In an embodiment, the diameter of the second electrode 163 may not be constant along the third direction DR3. A diameter of a portion of the second electrode 163 surrounded by the first electrode 161 and the second interlayer insulating layer 132 may be greater than a diameter of a portion of the second electrode 163 surrounded by the first interlayer insulating layer 130.

Referring to FIG. 8, as in the embodiment shown in FIG. 7, the second electrode 163 may be not only located within a space surrounded by the inner surface of the first electrode 161 and the inner surface of the first interlayer insulating layer 130, but also further located between the plurality of first interlayer insulating layers 130 located on the both sides of the first electrode 161 along the third direction DR3. A diameter of a portion of the second electrode 163 surrounded by the first electrode 161 and the second interlayer insulating layer 132 may be greater than a diameter of a portion of the second electrode 163 surrounded by the first interlayer insulating layer 130.

In the embodiment shown in FIG. 8, unlike the embodiment shown in FIG. 7, the first electrode 161 may include a vertical portion 161V extending in the direction perpendicular to the upper surface of the substrate 110 between the two first interlayer insulating layers 130 adjacent in the third direction DR3 perpendicular to the upper surface of the substrate 110, and two horizontal portions 161H extending from both end portions of the vertical portion 161V in the direction parallel to the upper surface of the substrate 110. The second electrode 163 may be further located between the two horizontal portions 161H. The second electrode 163 may include a portion protruding in a diameter direction from the external circumferential surface of a portion extending in the third direction DR3 toward an inner surface of the vertical portion 161V of the first electrode 161. A portion of the second electrode 163 protruding in the diameter direction may be located within a space surrounded by the vertical portion 161V and the two horizontal portions 161H of the first electrode 161.

In the embodiment shown in FIG. 7, the first dielectric layer 162 may be in contact with a part of surfaces facing in the third direction DR3 between the plurality of first interlayer insulating layers 130 stacked in the third direction DR3, that is, a part of the upper surface and the lower surface of each of the plurality of first interlayer insulating layers 130. Alternatively, in the embodiment shown in FIG. 8, the first dielectric layer 162 may be spaced apart from the upper surface and the lower surface of each of the plurality of first interlayer insulating layers 130 by the horizontal portions 161H of the first electrode 161.

Referring to FIG. 9, as in the embodiment shown in FIG. 8, the first electrode 161 may include the vertical portion 161V extending in the direction perpendicular to the upper surface of the substrate 110 between the two first interlayer insulating layers 130 adjacent in the third direction DR3 perpendicular to the upper surface of the substrate 110, and the two horizontal portions 161H extending from both end portions of the vertical portion 161V in the direction parallel to the upper surface of the substrate 110. The second electrode 163 may be further located between the two horizontal portions 161H.

In the embodiment shown in FIG. 8, unlike the embodiment shown in FIG. 7, the second electrode 163 may be further located on the upper surface and the lower surface of each of the two horizontal portions 161H of the first electrode 161. The second electrode 163 may surround both surfaces of the horizontal portion 161H of the first electrode 161 along the third direction DR3 and an inner surface of the horizontal portion 161H. The second electrode 163 may be further located between the horizontal portion 161H of the two first electrodes 161 adjacent in the third direction DR3.

In an embodiment, a diameter of a portion of the second electrode 163 surround by the inner surface of the vertical portion 161V of the first electrode 161 may be greater than a diameter of a portion of the second electrode 163 surround by the inner surface of the horizontal portion 161H of the first electrode 161. A diameter of a portion of the second electrode 163 surround by the inner surface of the first interlayer insulating layer 130 may be greater than a diameter of a portion of the second electrode 163 surround by the inner surface of the horizontal portion 161H of the first electrode 161. A diameter of a portion of the second electrode 163 surround by the inner surface of the vertical portion 161V of the first electrode 161 may be substantially the same as a diameter of a portion of the second electrode 163 surround by the inner surface of the first interlayer insulating layer 130, but is not limited thereto.

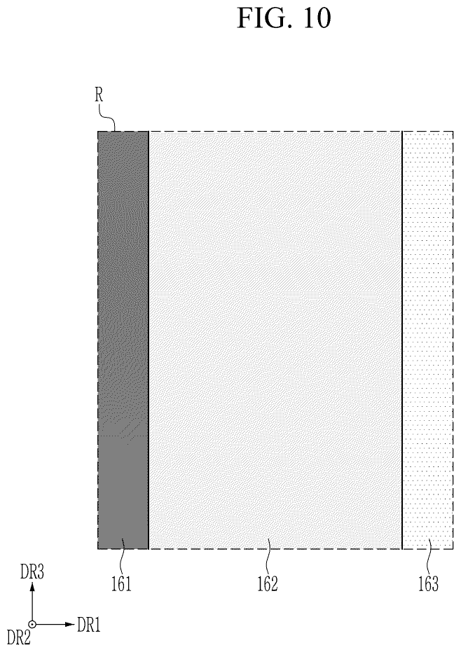

Hereinafter, a stacking structure of a data storage portion of a semiconductor device according to various embodiments will be described with reference to FIG. 10 to FIG. 12.

FIG. 10 to FIG. 12 are cross-sectional views of semiconductor devices according to various embodiments showing enlarged view of region R of FIG. 3. The description of the first electrode 161, the first dielectric layer 162, and the second electrode 163 described later may be equally applied to the third electrode 171, the second dielectric layer 172, and the fourth electrode 173, respectively.

Referring to FIG. 10, the first dielectric layer 162 may be formed as a single layer. The first dielectric layer 162 may include, for example, a high-dielectric material, a ferroelectric material, or an antiferroelectric material.

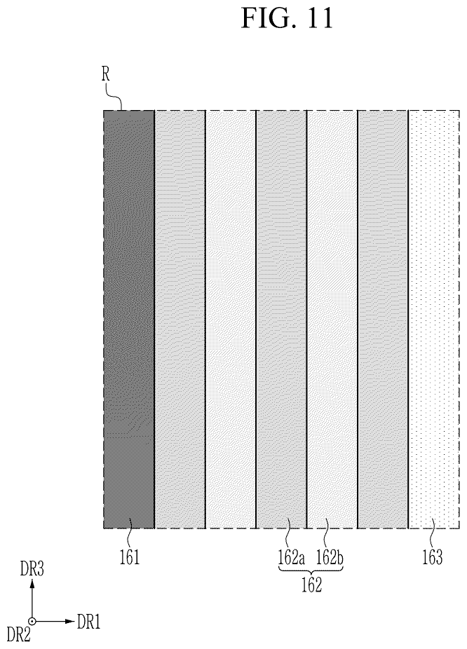

Referring to FIG. 11, the first dielectric layer 162 may be formed of multiple layers. In an embodiment, in the first dielectric layer 162, two different material layers may be alternately stacked. For example, the first dielectric layer 162 may include at least one first material layer 162a and at least one second material layer 162b alternately stacked between the first electrode 161 and the second electrode 163. Each of the first material layer 162a and the second material layer 162b may include a high-dielectric material, a ferroelectric material, or an antiferroelectric material. For example, the first material layer 162a may include a high-dielectric material, and the second material layer 162b may include a ferroelectric material or antiferroelectric material. As another example, the first material layer 162a and the second material layer 162b may include different ferroelectric materials.

The embodiment is not limited to what is illustrated in FIG. 11. The number and stack sequence of material layers included in the first dielectric layer 162 may be variously modified.

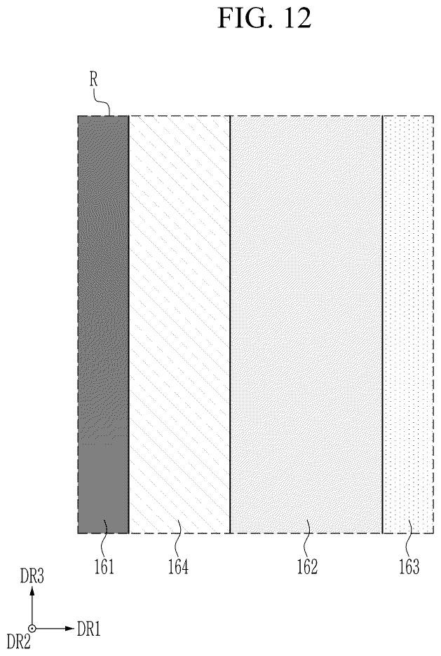

Referring to FIG. 12, a semiconductor layer 164 may be further located between the first electrode 161 and the second electrode 163. In an embodiment, the first dielectric layer 162 and the semiconductor layer 164 may be located between the first electrode 161 and the second electrode 163. For example, the first dielectric layer 162 may include a ferroelectric material. For example, the semiconductor layer 164 may include an oxide semiconductor material such as IGZO, but is not limited thereto. The semiconductor material included in the semiconductor layer 164 may be variously modified.

In the embodiment shown in FIG. 12, it is illustrated that the semiconductor layer 164 is adjacent to the first electrode 161 and the first dielectric layer 162 is adjacent to the second electrode 163, but it is not limited thereto. For example, the first dielectric layer 162 may be adjacent to the first electrode 161, and the semiconductor layer 164 may be adjacent to the second electrode 163.

According to an embodiment, since the first dielectric layer 162 and the semiconductor layer 164 including a ferroelectric material are located between the first electrode 161 and the second electrode 163, the hysteresis curve of the first dielectric layer 162 may be shifted. In this case, a write voltage and a read voltage of a ferroelectric memory including the first data storage portion 160 may be set to be different, and the read voltage may be lowered.

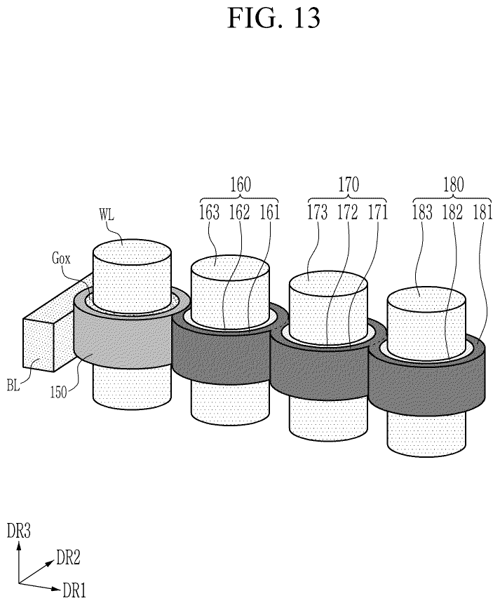

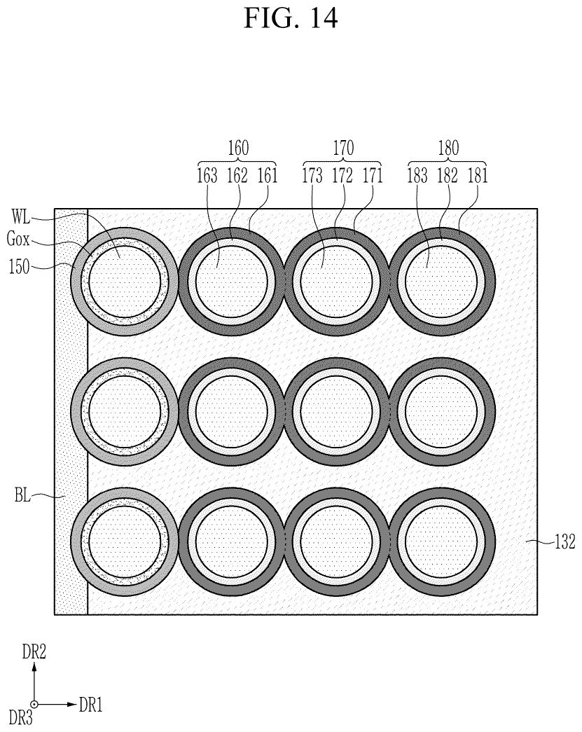

Hereinafter, a modified example of a semiconductor device according to an embodiment shown in FIG. 1 to FIG. 4 will be described with reference to FIG. 13 and FIG. 14.

FIG. 13 is a perspective view of a semiconductor device according to an embodiment. FIG. 14 is a top plan view of a semiconductor device according to an embodiment. The embodiment shown in FIG. 13 and FIG. 14 may be significantly the same as the embodiment shown in FIG. 1 to FIG. 4. In the embodiment shown in FIG. 13 and FIG. 14, the same components as the embodiment shown in FIG. 1 to FIG. 4 may be referred to with the same reference numerals. Hereinafter, regarding the embodiment shown in FIG. 13 and FIG. 14, differences from the previous embodiments will be mainly described. The embodiment shown in FIG. 13 and FIG. 14 may be partially different from the previous embodiment in that a third data storage portion 180 is further included.

Referring to FIG. 13 and FIG. 14, a semiconductor device according to an embodiment may further include the third data storage portion 180 connected to the second data storage portion 170. The third data storage portion 180 may include a fifth electrode 181 connected to the third electrode 171, a sixth electrode 183 surrounded by the fifth electrode 181, and a third dielectric layer 182 located between the fifth electrode 181 and the sixth electrode 183. The description of the third electrode 171, the fourth electrode 173, and the second dielectric layer 172 may be applied to the fifth electrode 181, the sixth electrode 183, and the third dielectric layer 182 in the same or similar way, and redundant description thereof will be omitted.

In an embodiment, the fifth electrode 181 may be connected to the third electrode 171 in the first direction DR1. A part of the third electrode 171 adjacent to the fifth electrode 181 may be covered with the fifth electrode 181. The fifth electrode 181 may cover a part of the external circumferential surface of the third electrode 171.

In an embodiment, the fifth electrode 181 may be in contact with the third electrode 171. The fifth electrode 181 may be in contact with a part of the external circumferential surface of the third electrode 171. For example, since the external circumferential surface of the third electrode 171 is a curved surface, a surface of the fifth electrode 181 in contact with the external circumferential surface of the third electrode 171 may include a curved surface.

In an embodiment, the fifth electrode 181 may include the same material as the third electrode 171. In this case, the fifth electrode 181 may be integrally formed with the third electrode 171. However, the embodiment is not limited thereto. For example, the fifth electrode 181 may include a different material from the third electrode 171.

The first electrode 161 may be connected to a first side of the third electrode 171 according to the first direction DR1, and the fifth electrode 181 may be connected to a second side of the third electrode 171 according to the first direction DR1.

In an embodiment, the fifth electrode 181 may surround the sixth electrode 183. The fifth electrode 181 may surround an external circumferential surface of the sixth electrode 183. In this case, the fifth electrode 181 may not surround the entire external circumferential surface of the sixth electrode 183. For example, the fifth electrode 181 may surround a region overlapping with the fifth electrode 181 in the first direction DR1 among the external circumferential surface of the sixth electrode 183.

In an embodiment, the sixth electrode 183 may extend in the third direction DR3 perpendicular to the upper surface of the substrate 110. The sixth electrode 183 may penetrate the fifth electrode 181 in the third direction DR3. For example, the sixth electrode 183 may have a pillar shape, and the fifth electrode 181 may have a ring shape.

By the third dielectric layer 182, the fifth electrode 181 and the sixth electrode 183 may be spaced apart. In an embodiment, the third dielectric layer 182 may be located on an inner surface of the fifth electrode 181. The third dielectric layer 182 may be located on the external circumferential surface of the sixth electrode 183. In an embodiment, the third dielectric layer 182 may surround the sixth electrode 183 on an inner side of the fifth electrode 181.

In an embodiment, a length of the third dielectric layer 182 along the third direction DR3 may be substantially the same as a length of the fifth electrode 181 along the third direction DR3, but is not limited thereto.

The fifth electrode 181, the third dielectric layer 182, and the sixth electrode 183 may have the same central axis. The third dielectric layer 182 may have a thickness in a diameter direction centered on a central axis of the fifth electrode 181, the third dielectric layer 182, and the sixth electrode 183. The thickness of the third dielectric layer 182 may mean a distance between the fifth electrode 181 and the sixth electrode 183. A distance between the fifth electrode 181 and the sixth electrode 183 may mean a distance between the inner surface of the fifth electrode 181 and the external circumferential surface of the sixth electrode 183.

The fifth electrode 181 and the sixth electrode 183 may include a conductive material. Each of the fifth electrode 181 and the sixth electrode 183 may include, for example, at least one among a metallic material, a conductive metal nitride, and a doped semiconductor material. The third dielectric layer 182 may include at least one among a high-dielectric material, a ferroelectric material, or an antiferroelectric material.

In an embodiment, the fifth electrode 181 may include the same material as the first electrode 161 and the third electrode 171, but is not limited thereto. For example, the fifth electrode 181 may include a different material from at least one among the first electrode 161 and the third electrode 171. In an embodiment, the sixth electrode 183 may include the same material as the second electrode 163 and the fourth electrode 173, but is not limited thereto. For example, the sixth electrode 183 may include a different material from at least one among the second electrode 163 and the fourth electrode 173.

In an embodiment, the voltage may be independently applied the second electrode 163 and the fourth electrode 173. For example, the voltage may be applied to the second electrode 163 and the fourth electrode 173 at different timings, and voltages of different magnitudes may be applied to the second electrode 163 and the fourth electrode 173.

In an embodiment, different information may be stored in the first data storage portion 160, the second data storage portion 170, and the third data storage portion 180. For example, different voltages may be applied to the second electrode 163, the fourth electrode 173, and the sixth electrode 183. As another example, at least one of the thickness, remanent polarization Pᵣ, or area of the first dielectric layer 162, the second dielectric layer 172, and the third dielectric layer 182 may be different.

In an embodiment, since the first data storage portion 160, the second data storage portion 170, and the third data storage portion 180 may store different information, one memory cell including the first data storage portion 160, the second data storage portion 170, and the third data storage portion 180 may store at least three bits of data. However, the embodiment is not limited thereto. For example, one memory cell including the first data storage portion 160, the second data storage portion 170, and the third data storage portion 180 may store one bit of data. In this case, the capacitance of the capacitor may be increased compared to a memory cell including only one data storage portion (e.g., a memory cell including only the first data storage portion 160).

In an embodiment, the semiconductor device may include the plurality of first data storage portion 160 respectively connected to the plurality of semiconductor patterns 150, the plurality of second data storage portions 170, connected to the plurality of first data storage portion 160, respectively, and a plurality of third data storage portions 180 connected to the plurality of second data storage portions 170, respectively. The plurality of first data storage portion 160 may be disposed to be spaced apart along the second direction DR2. Although not shown in the drawings, the plurality of first data storage portion 160 may be further disposed to be spaced apart along the first direction DR1. The plurality of first data storage portion 160 may be stacked along the third direction DR3. The plurality of second data storage portions 170 may be disposed to be spaced apart along the second direction DR2. Although not shown in the drawings, the plurality of second data storage portions 170 may be further disposed to be spaced apart along the first direction DR1. The plurality of second data storage portions 170 may be stacked along the third direction DR3.

In an embodiment, the plurality of third data storage portions 180 may be disposed to be spaced apart along the second direction DR2. Although not shown in the drawings, the plurality of third data storage portions 180 may be further disposed to be spaced apart along the first direction DR1. The plurality of third data storage portions 180 may be stacked along the third direction DR3.

In an embodiment, the plurality of third data storage portions 180 stacked along the third direction DR3 may include a plurality of fifth electrodes 181 disposed spaced apart along the third direction DR3, a single sixth electrode 183 extending in the third direction DR3 to penetrate the plurality of fifth electrodes 181, and a plurality of third dielectric layers 182 located between each of the plurality of fifth electrodes 181 and the single sixth electrode 183. However, the embodiment is not limited thereto. For example, a single third dielectric layer 182 may be located between each of the plurality of fifth electrodes 181 and the single sixth electrode 183 disposed to be spaced apart along the third direction DR3.

In the embodiment shown in FIG. 13 and FIG. 14, the semiconductor device may include three data storage portions 160, 170, and 180 connected to one semiconductor pattern 150. In the embodiment shown in FIG. 13 and FIG. 14, since one data storage portion (e.g., the third data storage portion 180 is further included compared to the embodiment shown in FIG. 1 to FIG. 4, the capacitance of the capacitor of one memory cell may increase or one memory cell may store more data although the area occupied by one memory cell may increase. In addition, since a semiconductor device according to an embodiment has a structure in which the fifth electrode 181 connected to the third electrode 171 surrounds the sixth electrode 183 and the sixth electrode 183 penetrates the fifth electrode 181 and extends in the direction perpendicular to the upper surface of the substrate 110, an increase in the area of a unit cell may be minimized.

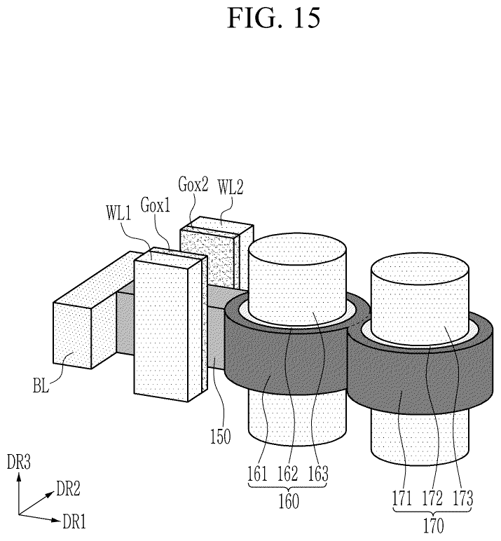

Hereinafter, various modification examples of a semiconductor device according to an embodiment shown in FIG. 1 to FIG. 4 will be described with reference to FIG. 15 to FIG. 17.

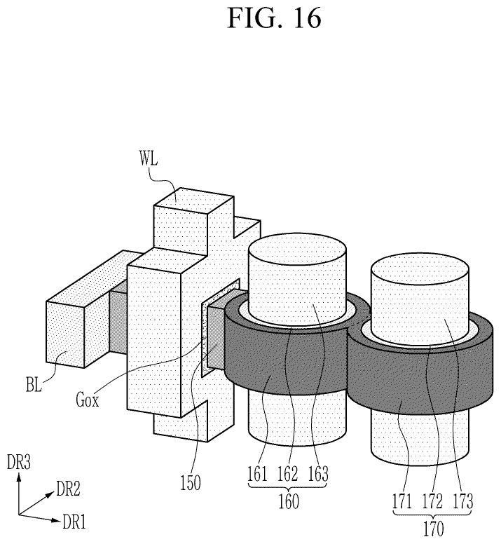

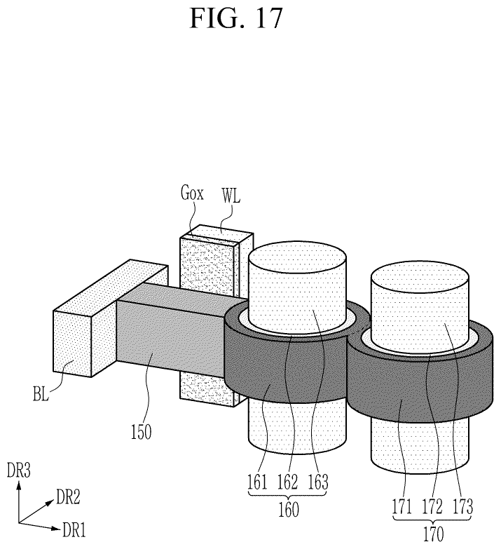

FIG. 15 is a perspective view of a semiconductor device according to an embodiment. FIG. 16 is a perspective view of a semiconductor device according to an embodiment. FIG. 17 is a perspective view of a semiconductor device according to an embodiment. Each of the embodiments shown in FIG. 15, FIG. 16, and FIG. 17 may be significantly the same as the embodiment shown in FIG. 1 to FIG. 4. In each of the embodiments shown in FIG. 15, FIG. 16, and FIG. 17, the same components as the embodiment shown in FIG. 1 to FIG. 4 may be referred to with the same reference numerals. Hereinafter, regarding each of the embodiments shown in FIG. 15, FIG. 16, and FIG. 17, differences from the previous embodiments will be mainly described. Each of the embodiments shown in FIG. 15, FIG. 16, and FIG. 17 may be partially different from the previous embodiment in the structure and shape of the semiconductor pattern 150 and the word line WL.

Referring to FIG. 15, a semiconductor device according to an embodiment may include the semiconductor pattern 150 extending along the first direction DR1. A first side of the semiconductor pattern 150 according to the first direction DR1 end portion may be connected to the bit line BL. The bit line BL may extend in the second direction DR2 parallel to the upper surface of the substrate 110. A second side of the semiconductor pattern 150 according to the first direction DR1 end portion may be connected to the first electrode 161 of the first data storage portion 160.

A semiconductor device according to an embodiment may include a first word line WL1 and a second word line WL2 located on both sides of the semiconductor pattern 150 along the second direction DR2. The semiconductor pattern 150 may be located between the first word line WL1 and the second word line WL2. A first gate insulation layer Gox1 may be located between the first word line WL1 and the semiconductor pattern 150. A second gate insulation layer Gox may be located between the second word line WL2 and the semiconductor pattern 150. The first word line WL1 and the second word line WL2 may extend in the third direction DR3 perpendicular to the upper surface of the substrate 110. The first gate insulation layer Gox1 and the second gate insulation layer Gox may extend in the third direction DR3 perpendicular to the upper surface of the substrate 110.

A semiconductor device according to an embodiment may have a double gate structure in which one memory cell is electrically connected to two word lines. The same voltage or different voltages may be applied to the first word line WL1 and the second word line WL2. For example, when different voltages are applied to the first word line WL1 and the second word line WL2, one of the first word line WL1 and the second word line WL2 may be used as a front gate, and the other thereof may be used as a back gate.

Although not shown in the drawings, a semiconductor device according to an embodiment may include the plurality of semiconductor patterns 150 stacked in the third direction DR3, and the first word line WL1 and the second word line WL2 may extend in the third direction DR3 on both sides along the second direction DR2 of the plurality of semiconductor patterns 150 stacked in the third direction DR3.

Referring to FIG. 16, as in the embodiment shown in FIG. 15, the semiconductor pattern 150 may extend along the first direction DR1. A first side of the semiconductor pattern 150 according to the first direction DR1 end portion may be connected to the bit line BL. The bit line BL may extend in the second direction DR2 parallel to the upper surface of the substrate 110. A second side of the semiconductor pattern 150 according to the first direction DR1 end portion may be connected to the first electrode 161 of the first data storage portion 160.

In the embodiment shown in FIG. 16, unlike the embodiment shown in FIG. 15, a semiconductor device according to an embodiment may include the single word line WL adjacent to the semiconductor pattern 150. The word line WL may extend in the third direction DR3 perpendicular to the upper surface of the substrate 110. In an embodiment, the word line WL may surround the semiconductor pattern 150. The word line WL may surround an external circumferential surface centered on a central axis along the first direction DR1 of the semiconductor pattern 150. In this case, the word line WL may not surround the entire external circumferential surface of the semiconductor pattern 150. The word line WL may surround the channel region of the semiconductor pattern 150. For example, the channel region of the semiconductor pattern 150 may be located between both end portions along the first direction DR1 of the semiconductor pattern 150. The word line WL may surround the external circumferential surface between both end portions along the first direction DR1 of the semiconductor pattern 150. A semiconductor device according to an embodiment may have a gate-all-around (GAA) structure in which the word line WL surrounds the channel region of the semiconductor pattern 150.

In an embodiment, the gate insulation layer Gox may be located between the word line WL and the semiconductor pattern 150. The gate insulation layer Gox may surround the semiconductor pattern 150.

Although not shown in the drawings, a semiconductor device according to an embodiment may include the plurality of semiconductor patterns 150 stacked in the third direction DR3, and the word line WL may surround the plurality of semiconductor patterns 150 stacked in the third direction DR3 and may extend in the third direction DR3. For example, a width of a portion of the word line WL along the second direction DR2 surrounding the semiconductor pattern 150 may be greater than a width of a portion connecting portions of the word line WL along the second direction DR2 that surround two semiconductor patterns 150 adjacent in the third direction DR3, respectively, but it is not limited thereto. For example, a width along the second direction DR2 of the word line WL extending along the third direction DR3 may be constant.

Referring to FIG. 17, as in the embodiment shown in FIG. 15, the semiconductor pattern 150 may extend along the first direction DR1. A first side of the semiconductor pattern 150 according to the first direction DR1 end portion may be connected to the bit line BL. The bit line BL may extend in the second direction DR2 parallel to the upper surface of the substrate 110. A second side of the semiconductor pattern 150 according to the first direction DR1 end portion may be connected to the first electrode 161 of the first data storage portion 160.

In the embodiment shown in FIG. 17, unlike the embodiment shown in FIG. 15, a semiconductor device according to an embodiment may include the single word line WL adjacent to the semiconductor pattern 150. A semiconductor device according to an embodiment may have a single gate structure in which one memory cell is electrically connected to one word line.

In an embodiment, the word line WL may be located on a first side of the semiconductor pattern 150 along the second direction DR2. The gate insulation layer Gox may be located between the word line WL and the semiconductor pattern 150. The word line WL may extend in the third direction DR3 perpendicular to the upper surface of the substrate 110. The gate insulation layer Gox may extend in the third direction DR3 perpendicular to the upper surface of the substrate 110.

Although not shown in the drawings, a semiconductor device according to an embodiment may include the plurality of semiconductor patterns 150 stacked in the third direction DR3, and the word line WL may extend in the third direction DR3 on first side along the second direction DR2 of the plurality of semiconductor patterns 150 stacked in the third direction DR3.

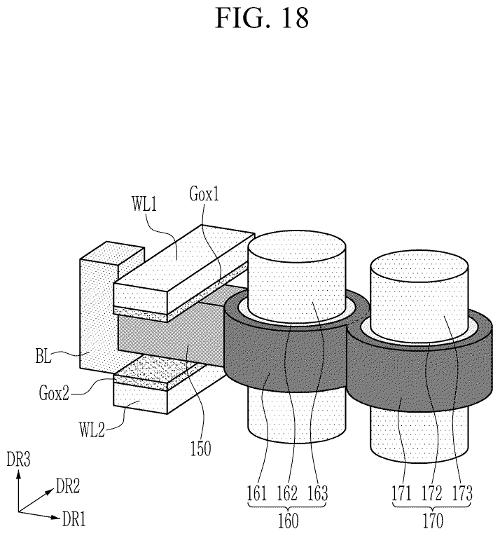

Hereinafter, various modification examples of a semiconductor device according to an embodiment shown in FIG. 1 to FIG. 4 will be described with reference to FIG. 18 to FIG. 20.

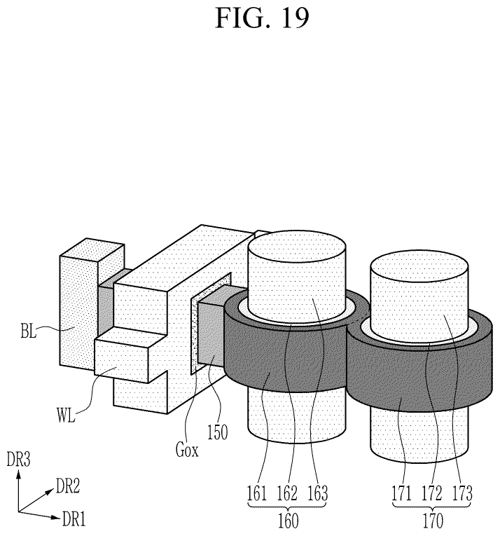

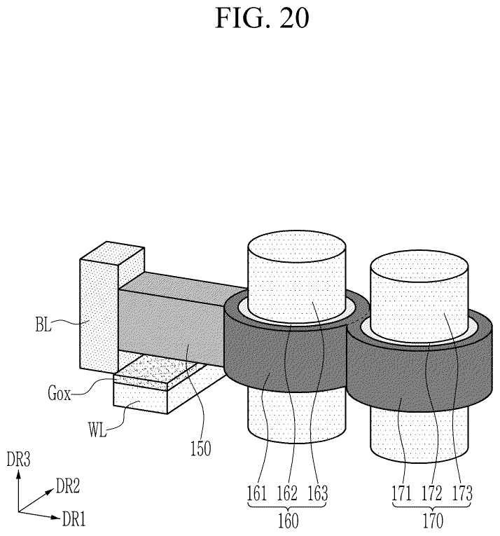

FIG. 18 is a perspective view of a semiconductor device according to an embodiment. FIG. 19 is a perspective view of a semiconductor device according to an embodiment. FIG. 20 is a perspective view of a semiconductor device according to an embodiment. Each of the embodiments shown in FIG. 18, FIG. 19, and FIG. 20 may be significantly the same as the embodiment shown in FIG. 1 to FIG. 4. In each of the embodiments shown in FIG. 18, FIG. 19, and FIG. 20, the same components as the embodiment shown in FIG. 1 to FIG. 4 may be referred to with the same reference numerals. Hereinafter, regarding each of the embodiments shown in FIG. 18, FIG. 19, and FIG. 20, differences from the previous embodiments will be mainly described. Each of the embodiments shown in FIG. 18, FIG. 19, and FIG. 20 may be partially different from the previous embodiment in the structure and shape of the semiconductor pattern 150, the word line WL, and the bit line BL.

Referring to FIG. 18, a semiconductor device according to an embodiment may include the semiconductor pattern 150 extending along the first direction DR1. A first side of the semiconductor pattern 150 according to the first direction DR1 end portion may be connected to the bit line BL. In the embodiment shown in FIG. 18, unlike the embodiment shown in FIG. 15, the bit line BL may extend in the third direction DR3 perpendicular to the upper surface of the substrate 110. A second side of the semiconductor pattern 150 according to the first direction DR1 end portion may be connected to the first electrode 161 of the first data storage portion 160.

A semiconductor device according to an embodiment may include the first word line WL1 and the second word line WL2 located on both sides of the semiconductor pattern 150 along the third direction DR3. The semiconductor pattern 150 may be located between the first word line WL1 and the second word line WL2. The first gate insulation layer Gox1 may be located between the first word line WL1 and the semiconductor pattern 150. The second gate insulation layer Gox may be located between the second word line WL2 and the semiconductor pattern 150. The first word line WL1 and the second word line WL2 may extend in the second direction DR2 parallel to the upper surface of the substrate 110. The first gate insulation layer Gox1 and the second gate insulation layer Gox may extend in the second direction DR2 parallel to the upper surface of the substrate 110.

A semiconductor device according to an embodiment may have a double gate structure in which one memory cell is electrically connected to two word lines. The same voltage or different voltages may be applied to the first word line WL1 and the second word line WL2. For example, when different voltages are applied to the first word line WL1 and the second word line WL2, one of the first word line WL1 and the second word line WL2 may be used as a front gate, and the other thereof may be used as a back gate.

Although not shown in the drawings, a semiconductor device according to an embodiment may include the plurality of semiconductor patterns 150 stacked in the third direction DR3, and the first word line WL1 and the second word line WL2 may extend in the second direction DR2 on both sides along the third direction DR3 of the plurality of semiconductor patterns 150 stacked in the third direction DR3.

Referring to FIG. 19, as in the embodiment shown in FIG. 18, the semiconductor pattern 150 may extend along the first direction DR1. A first side of the semiconductor pattern 150 according to the first direction DR1 end portion may be connected to the bit line BL. The bit line BL may extend in the third direction DR3 perpendicular to the upper surface of the substrate 110. A second side of the semiconductor pattern 150 according to the first direction DR1 end portion may be connected to the first electrode 161 of the first data storage portion 160.

In the embodiment shown in FIG. 19, unlike the embodiment shown in FIG. 18, a semiconductor device according to an embodiment may include the single word line WL adjacent to the semiconductor pattern 150. The word line WL may extend in the second direction DR2 parallel to the upper surface of the substrate 110. In an embodiment, the word line WL may surround the semiconductor pattern 150. The word line WL may surround an external circumferential surface centered on a central axis along the first direction DR1 of the semiconductor pattern 150. In this case, the word line WL may not surround the entire external circumferential surface of the semiconductor pattern 150. The word line WL may surround the channel region of the semiconductor pattern 150. For example, the channel region of the semiconductor pattern 150 may be located between both end portions along the first direction DR1 of the semiconductor pattern 150. The word line WL may surround the external circumferential surface between both end portions along the first direction DR1 of the semiconductor pattern 150. A semiconductor device according to an embodiment may have a gate-all-around (GAA) structure in which the word line WL surrounds the channel region of the semiconductor pattern 150.

In an embodiment, the gate insulation layer Gox may be located between the word line WL and the semiconductor pattern 150. The gate insulation layer Gox may surround the semiconductor pattern 150.

Although not shown in the drawings, a semiconductor device according to an embodiment may include the plurality of semiconductor patterns 150 disposed spaced apart in the second direction DR2, and the word line WL may surround the plurality of semiconductor patterns 150 disposed spaced apart in the second direction DR2 and extend in the second direction DR2. For example, the width of a portion of the word line WL along the third direction DR3 surrounding the semiconductor pattern 150 may be greater than the width of a portion connecting portions of the word line WL along the third direction DR3 that surround the two semiconductor patterns 150 adjacent in the second direction DR2, respectively, but it is not limited thereto. For example, a width along the third direction DR3 of the word line WL extending along the second direction DR2 may be constant.

Referring to FIG. 20, as in the embodiment shown in FIG. 18, the semiconductor pattern 150 may extend along the first direction DR1. A first side of the semiconductor pattern 150 according to the first direction DR1 end portion may be connected to the bit line BL. The bit line BL may extend in the third direction DR3 perpendicular to the upper surface of the substrate 110. A second side of the semiconductor pattern 150 according to the first direction DR1 end portion may be connected to the first electrode 161 of the first data storage portion 160.

In the embodiment shown in FIG. 20, unlike the embodiment shown in FIG. 18, a semiconductor device according to an embodiment may include the single word line WL adjacent to the semiconductor pattern 150. A semiconductor device according to an embodiment may have a single gate structure in which one memory cell is electrically connected to one word line.

In an embodiment, the word line WL may be located on a first side of the semiconductor pattern 150 along the third direction DR3. The gate insulation layer Gox may be located between the word line WL and the semiconductor pattern 150. The word line WL may extend in the second direction DR2 parallel to the upper surface of the substrate 110. The gate insulation layer Gox may extend in the second direction DR2 parallel to the upper surface of the substrate 110.

Although not shown in the drawings, a semiconductor device according to an embodiment may include the plurality of semiconductor patterns 150 disposed spaced apart in the second direction DR2, and the word line WL may extend in the second direction DR2 on a first side along the third direction DR3 of the plurality of semiconductor patterns 150 disposed spaced apart in the second direction DR2.

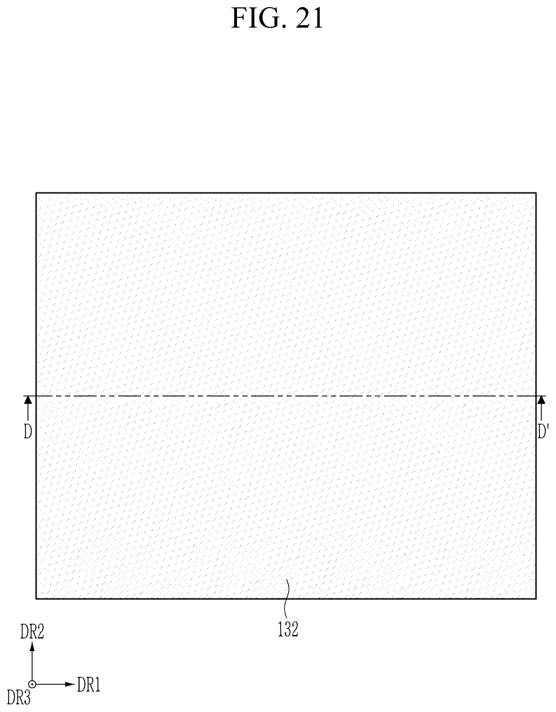

Hereinafter, a method of manufacturing a semiconductor device according to an embodiment shown in FIG. 1 to FIG. 4 will be described with reference to FIG. 21 to FIG. 36.

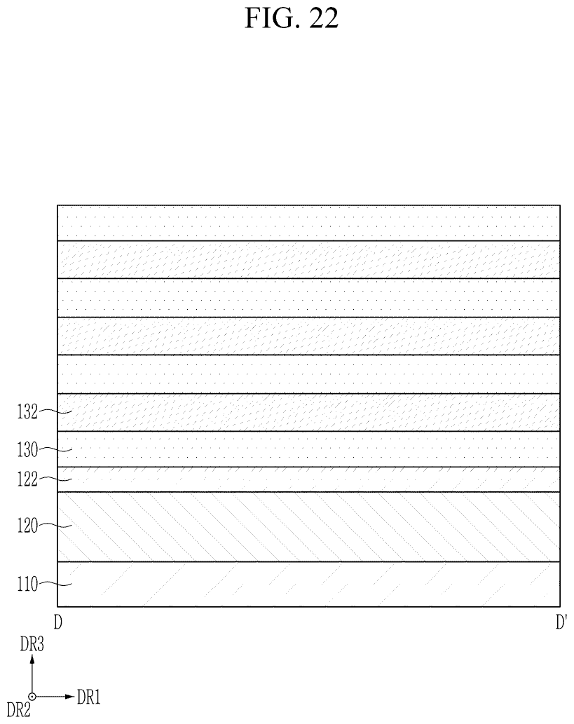

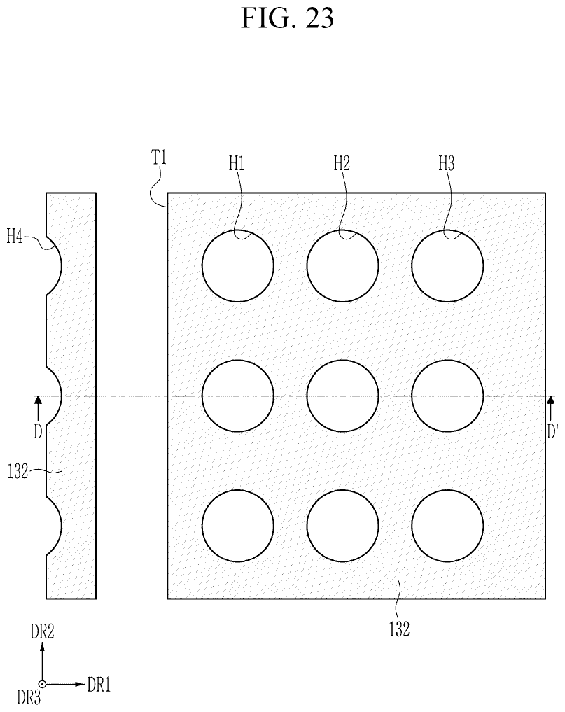

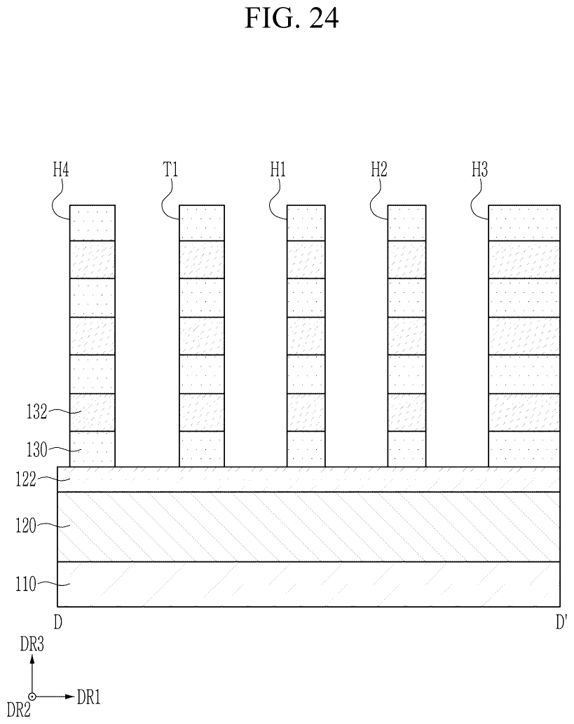

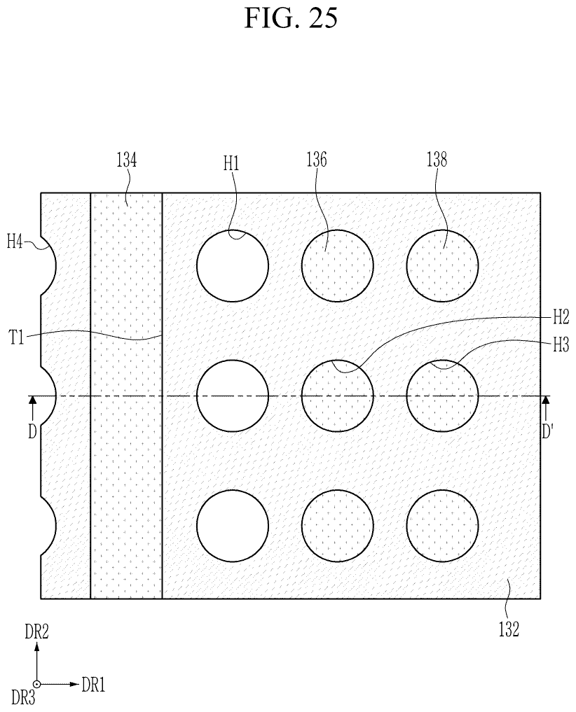

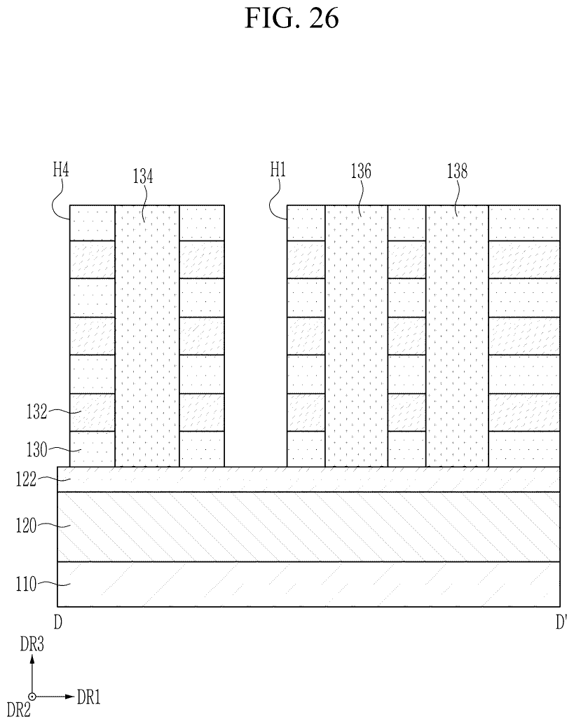

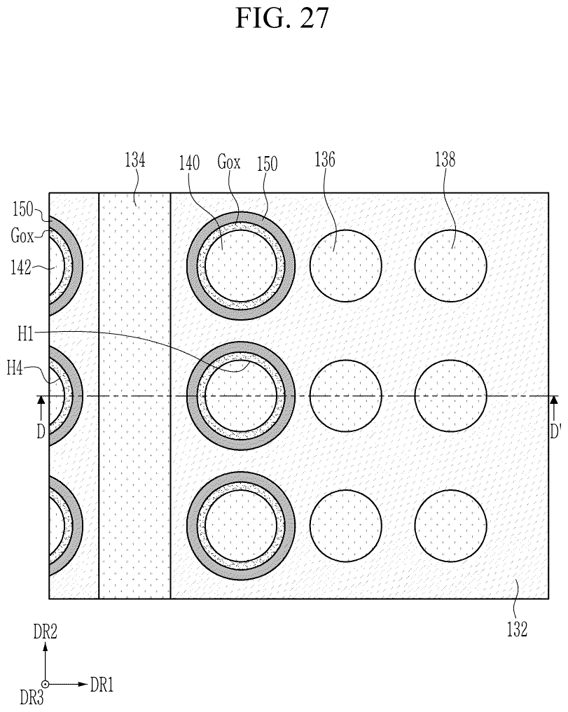

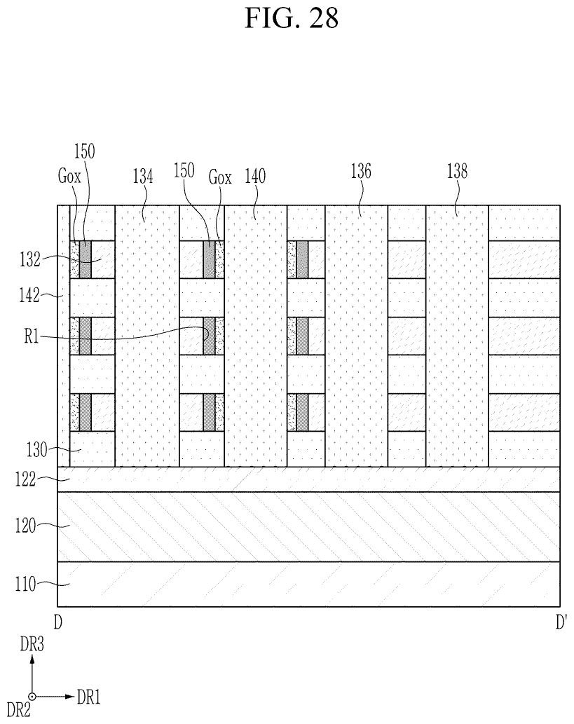

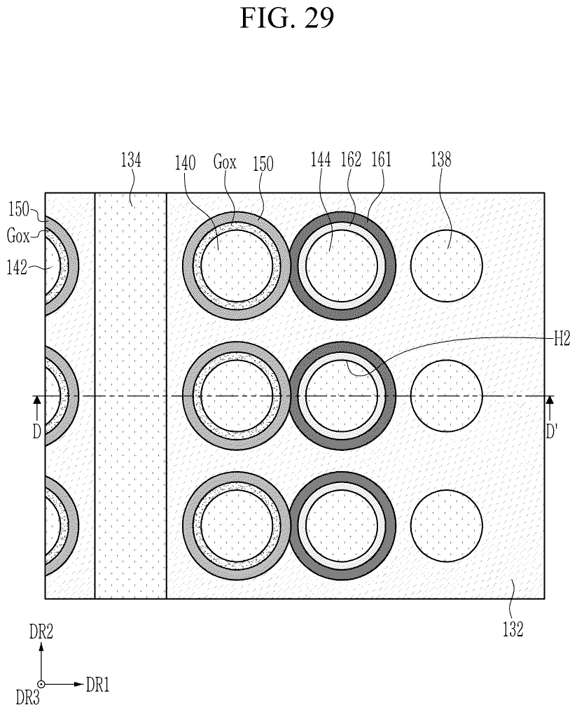

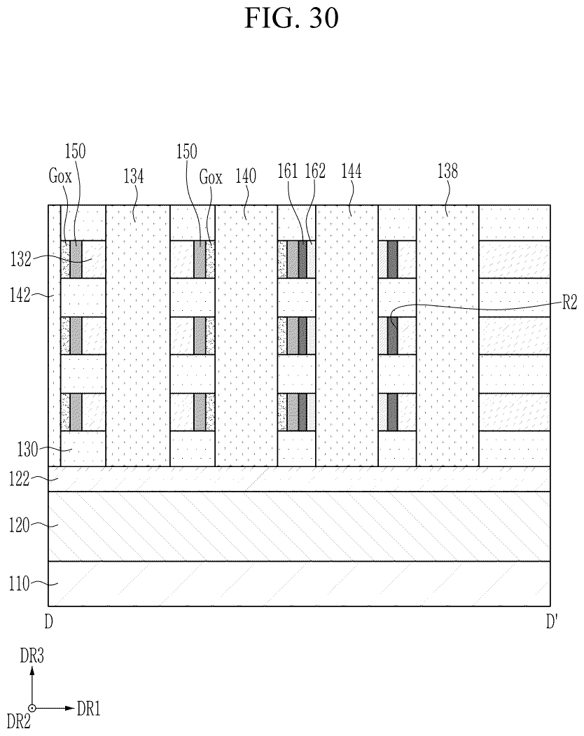

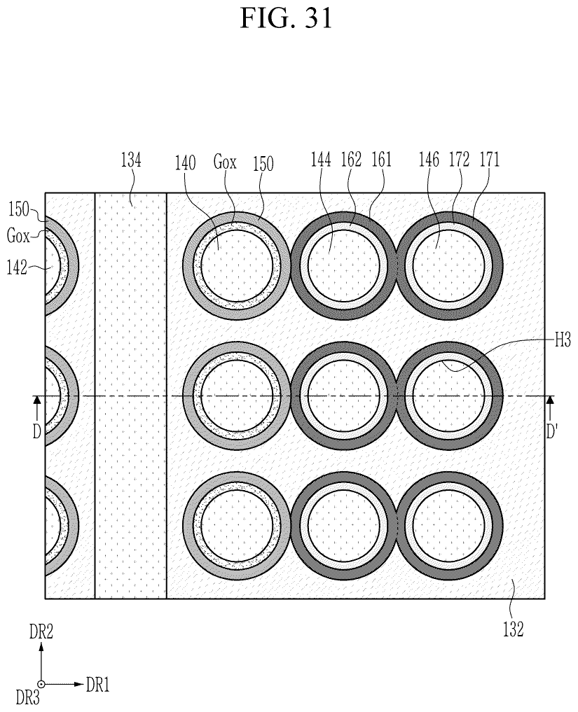

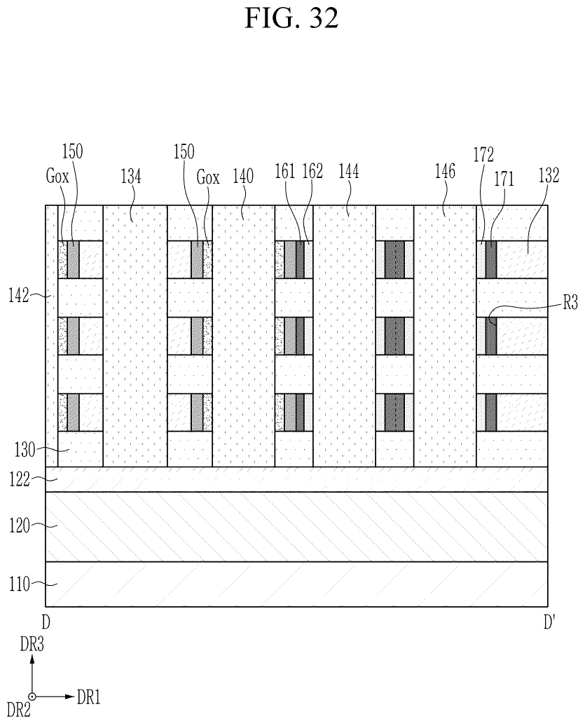

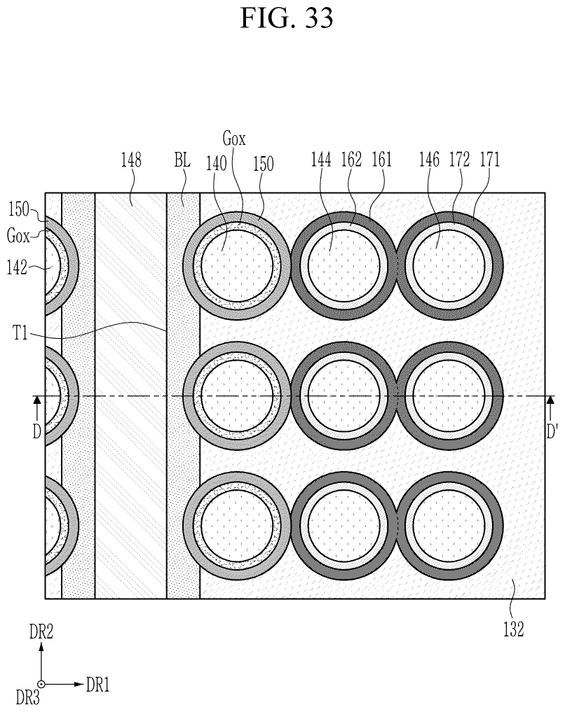

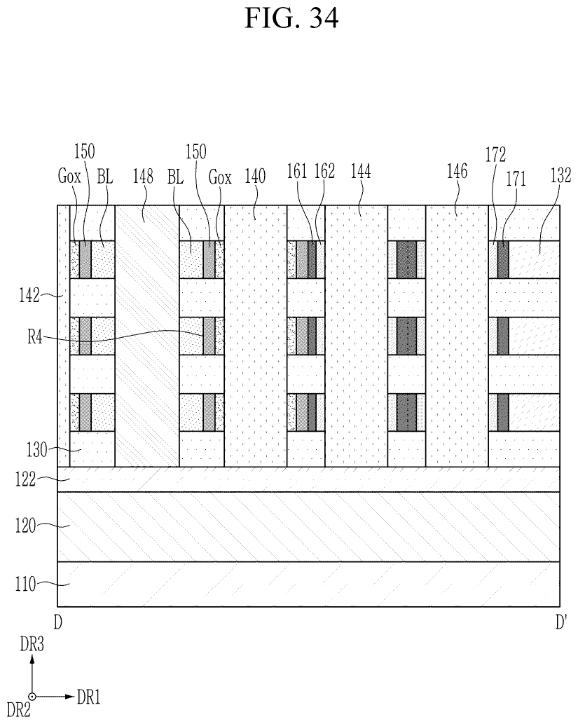

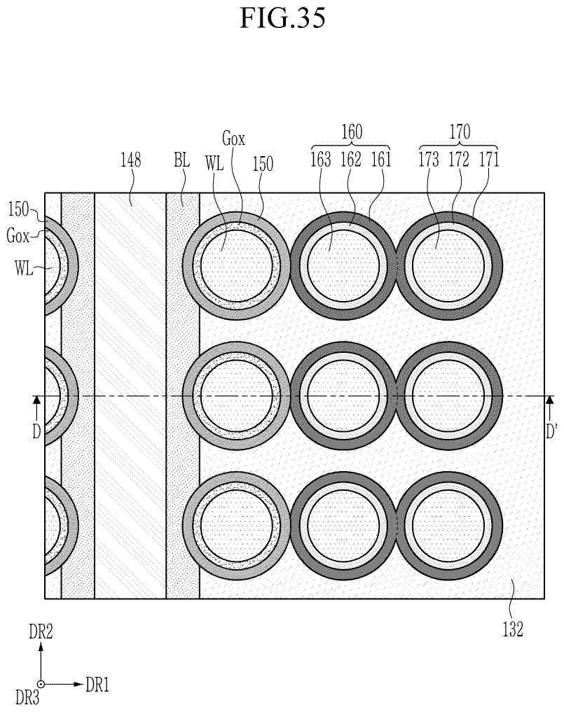

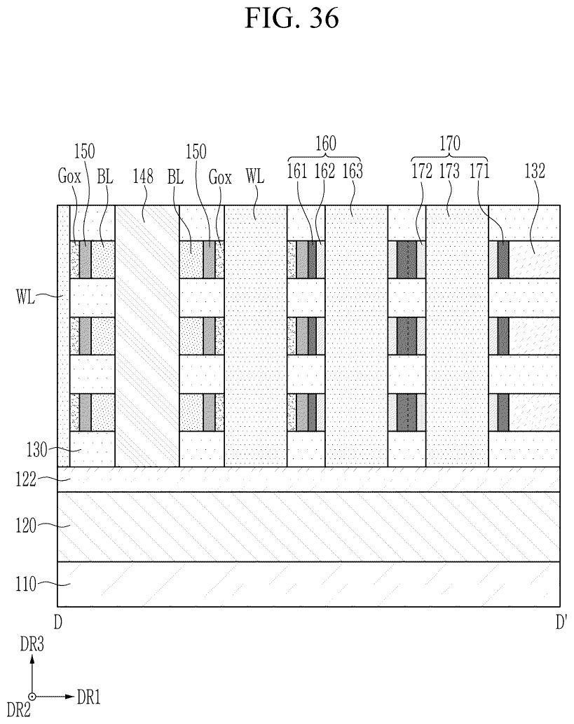

FIG. 21, FIG. 23, FIG. 25, FIG. 27, FIG. 29, FIG. 31, FIG. 33, and FIG. 35 are top plan views showing a part of a manufacturing process of a semiconductor device according to an embodiment. FIG. 22, FIG. 24, FIG. 26, FIG. 28, FIG. 30, FIG. 32, FIG. 34, and FIG. 36 are cross-sectional views showing a part of a manufacturing process of a semiconductor device according to an embodiment. FIG. 22, FIG. 24, FIG. 26, FIG. 28, FIG. 30, FIG. 32, FIG. 34, and FIG. 36 each are cross-sectional views taken along line D-D′ of FIG. 21, FIG. 23, FIG. 25, FIG. 27, FIG. 29, FIG. 31, FIG. 33, and FIG. 35, respectively. For convenience, FIG. 21, FIG. 23, FIG. 25, FIG. 27, FIG. 29, FIG. 31, FIG. 33, and FIG. 35 illustrate a plane in the same layer as the second interlayer insulating layer 132, but omits illustration of configurations (e.g., the first interlayer insulating layer 130) located on the second interlayer insulating layer 132.

Referring to FIG. 21 and FIG. 22, the first insulation layer 120, the second insulation layer 122, the plurality of first interlayer insulating layers 130, and the plurality of second interlayer insulating layers 132 may be formed on the substrate 110.

First, the first insulation layer 120 may be formed on the substrate 110, the second insulation layer 122 may be formed on the first insulation layer 120, and the plurality of first interlayer insulating layers 130 and the plurality of second interlayer insulating layers 132 may be alternately formed on the second insulation layer 122. The first insulation layer 120, the second insulation layer 122, the plurality of first interlayer insulating layers 130, and the plurality of second interlayer insulating layers 132 may be formed through a deposition process. Each of the first insulation layer 120, the second insulation layer 122, the plurality of first interlayer insulating layers 130, and the plurality of second interlayer insulating layers 132 may be formed by using a selected deposition process among chemical vapor deposition (CVD), physical vapor deposition (PVD), and atomic layer deposition (ALD), but it is not limited thereto.

Each of the first insulation layer 120, the second insulation layer 122, the first interlayer insulating layer 130, and the second interlayer insulating layer 132 may include an insulating material. For example, each of the first insulation layer 120, the second insulation layer 122, the first interlayer insulating layer 130, and the second interlayer insulating layer 132 may include silicon oxide, silicon nitride, silicon oxynitride, or a combination thereof, but are not limited thereto.

In an embodiment, the second insulation layer 122 may include a material having etch selectivity with respect to the first interlayer insulating layer 130 and the second interlayer insulating layer 132. In subsequent processes, the second insulation layer 122 may be used an etch-stop layer in the process of etching the plurality of first interlayer insulating layers 130 and the plurality of second interlayer insulating layers 132.

In an embodiment, the second interlayer insulating layer 132 may include a material having etch selectivity with respect to the first interlayer insulating layer 130. Accordingly, in a subsequent process, it is possible to selectively etch only the second interlayer insulating layer 132.

Referring to FIG. 23 and FIG. 24, the plurality of first interlayer insulating layers 130 and the plurality of second interlayer insulating layers 132 may be etched to form a trench T1 and a plurality of first holes H1, a plurality of second holes H2, a plurality of third holes H3, and a plurality of fourth holes H4.

First, by forming a photoresist pattern on an upper surface of an interlayer insulating layer located uppermost by using a photolithography process, a region where the trench T1, the plurality of first holes H1, the plurality of second holes H2, the plurality of third holes H3, and the plurality of fourth holes H4 are formed may be defined. For example, a region corresponding to an opening of the photoresist pattern may be defined as a region where the trench T1, the plurality of first holes H1, the plurality of second holes H2, the plurality of third holes H3, and the plurality of fourth holes H4 is formed. The trench T1, the plurality of first holes H1, the plurality of second holes H2, the plurality of third holes H3, and the plurality of fourth holes H4 may be formed by etching the interlayer insulating layers exposed by the opening of the photoresist pattern. For example, the plurality of first interlayer insulating layers 130 and the plurality of second interlayer insulating layers 132 may be etched until an upper surface of the second insulation layer 122 is exposed by the opening of the photoresist pattern.

The trench T1 may extend in the third direction DR3 and the second direction DR2. The first hole H1, the second hole H2, the third hole H3, and the fourth hole H4 may extend in the third direction DR3. For example, a planar shape of each of the first hole H1, the second hole H2, the third hole H3, and the fourth hole H4 may be circular, but is not limited thereto.

The first hole H1, the second hole H2, and the third hole H3 may be located to be spaced apart along the first direction DR1. The first hole H1, the second hole H2, and the third hole H3 may be sequentially disposed on a first side of the trench T1 along the first direction DR1. That is, the first hole H1 may be most adjacent to the trench T1, the third hole H3 may be most distal from the trench T1, and the second hole H2 may be located between the first hole H1 and the third hole H3.

The fourth hole H4 may be located symmetrical to the first hole H1 based on the trench T1. Although not shown in the drawings, a fifth hole symmetrical to the second hole H2 based on the trench T1 and a sixth hole symmetrical to the third hole H3 based on the trench T1 may also be formed together with the first hole H1, the second hole H2, the third hole H3, and the fourth hole H4.

In a subsequent process, the bit line BL may be formed through the trench T1. In a subsequent process, the semiconductor pattern 150, the gate insulation layer Gox, and the word line WL may be formed through the first hole H1 and the fourth hole H4. In a subsequent process, the first data storage portion 160 may be formed through the second hole H2. In a subsequent process, the second data storage portion 170 may be formed through the third hole H3. Although the description of the fifth hole and the sixth hole is omitted merely for convenience, the process regarding the second hole H2 and the third hole H3 may be equally applied to the fifth hole and the sixth hole.

In an embodiment, each of the plurality of first holes H1, the plurality of second holes H2, the plurality of third holes H3, and the plurality of fourth holes H4 may be disposed to be spaced apart along the second direction DR2. Although not shown in the drawings, a plurality of trenches T1 may be formed, and the plurality of trenches T1 may be disposed to be spaced apart in the first direction DR1.

Referring to FIG. 25 and FIG. 26, a first sacrificial layer 134 may be formed within the trench T1, a second sacrificial layer 136 may be formed within each second hole H2 may be formed, and a third sacrificial layer 138 may be formed within each third hole H3.

First, a sacrificial material layer filling the trench T1, the plurality of first holes H1, the plurality of second holes H2, the plurality of third holes H3, and the plurality of fourth holes H4 may be formed, and then the sacrificial material layer may be patterned. For example, the sacrificial material layer may be formed through a deposition process. For example, the photoresist pattern may be formed on an upper surface of the sacrificial material layer, and then the etching process may be performed by using the photoresist pattern, to etch portions of the sacrificial material layer located within the plurality of first holes H1 and the plurality of fourth holes H4. Portions of the sacrificial material layer located within the trench T1, the plurality of second holes H2, and the plurality of third holes H3 may remain. A portion of the sacrificial material layer located within the trench T1 may be referred to as the first sacrificial layer 134. A portion of the sacrificial material layer located within each second hole H2 may be referred to as the second sacrificial layer 136. A portion of the sacrificial material layer located within each third hole H3 may be referred to as the third sacrificial layer 138.

The first sacrificial layer 134, the second sacrificial layer 136, and the third sacrificial layer 138 may include an insulating material. The first sacrificial layer 134, the second sacrificial layer 136, and the third sacrificial layer 138 may include a material having etch selectivity with respect to the first interlayer insulating layer 130, the second interlayer insulating layer 132, and the second insulation layer 122.

Referring to FIG. 27 and FIG. 28, the plurality of semiconductor patterns 150 and a plurality of gate insulation layers Gox may be formed, a fourth sacrificial layer 140 may be formed within each first hole H1, and a fifth sacrificial layer 142 may be formed within each fourth hole H4.

First, a part of the plurality of second interlayer insulating layers 132 exposed through the plurality of first holes H1 and the plurality of fourth holes H4 may be etched. For example, the second interlayer insulating layer 132 may be etched by using a material having etch selectivity with respect to the first interlayer insulating layer 130, the second insulation layer 122, and sacrificial layers 134, 136, and 138. Accordingly, the plurality of second interlayer insulating layers 132 may be recessed in a diameter direction of each first hole H1 and each fourth hole H4, to form a plurality of first recesses R1. The plurality of first recesses R1 may have an inner surface of the second interlayer insulating layer 132 as a bottom surface, and have an upper surface and a lower surface of the plurality of first interlayer insulating layers 130 as both sidewalls.

Thereafter, the plurality of semiconductor patterns 150 and the plurality of gate insulation layers Gox may be formed. The plurality of semiconductor patterns 150 may be formed by depositing and patterning a semiconductor material layer, and the plurality of gate insulation layers Gox may be formed by depositing and patterning a gate insulating material layer. For example, the semiconductor material layer and the gate insulating material layer may be formed through an ALD process or a CVD process, but is not limited thereto.

The semiconductor material layer may be formed not only in the interior of the first recess R1 in each first hole H1 and each fourth hole H4 but also on the side surface of the plurality of first interlayer insulating layers 130. Thereafter, a portion of the semiconductor material layer located on the side surface of the plurality of first interlayer insulating layers 130 may be removed through an etch-back process. Accordingly, the semiconductor material layer may be separated in the third direction DR3 so that the plurality of semiconductor patterns 150 disposed spaced apart in the third direction DR3 may be formed.

The gate insulating material layer may be formed not only in the interior of the first recess R1 in each first hole H1 and each fourth hole H4 but also on the side surface of the plurality of first interlayer insulating layers 130. Thereafter, a portion of the gate insulating material layer located on the side surface of the plurality of first interlayer insulating layers 130 may be removed through an etch-back process. Accordingly, the gate insulating material layer may be separated in the third direction DR3 so that the plurality of gate insulation layers Gox disposed spaced apart in the third direction DR3 may be formed.

Each semiconductor pattern 150 and each gate insulation layer Gox may be located within each first recess R1. The semiconductor pattern 150 may cover the inner surface of the second interlayer insulating layer 132 within the first recess R1. The gate insulation layer Gox may cover the inner surface of the semiconductor pattern 150 within the first recess R1.

The semiconductor pattern 150 may include a semiconductor material. For example, the semiconductor pattern 150 may include silicon, germanium, or silicon-germanium. For example, the semiconductor pattern 150 may include monocrystalline silicon or polycrystalline silicon. However, the embodiment is not limited thereto. For example, the semiconductor pattern 150 may include an oxide semiconductor material such as indium gallium zinc oxide (IGZO). As another example, the semiconductor pattern 150 may include a 2-dimension semiconductor material such as molybdenum disulfide (MoS₂).

The gate insulation layer Gox may include at least one among a high-dielectric material, a silicon oxide, a silicon nitride, or a silicon oxynitride. The high-dielectric material may include, for example, at least one among hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

Thereafter, the fourth sacrificial layer 140 may be formed within each first hole H1, and form the fifth sacrificial layer 142 may be formed within each fourth hole H4. For example, after depositing the sacrificial material layer filling the plurality of first holes H1 and the plurality of fourth holes H4, through a planarization process, the fourth sacrificial layer 140 may be formed within each first hole H1, and the fifth sacrificial layer 142 may be formed within each fourth hole H4. The planarization process may be, e.g., a chemical mechanical polishing process (CMP), but is not limited thereto.

The fourth sacrificial layer 140 and the fifth sacrificial layer 142 may include an insulating material. The fourth sacrificial layer 140 and the fifth sacrificial layer 142 may include a material having etch selectivity with respect to the first interlayer insulating layer 130, the second interlayer insulating layer 132, and the second insulation layer 122.

In an embodiment, the plurality of semiconductor patterns 150 may be stacked in the third direction DR3. The first interlayer insulating layer 130 may be located between the plurality of semiconductor patterns 150 stacked in the third direction DR3. The plurality of semiconductor patterns 150 within the same layer may be disposed to be spaced apart along the second direction DR2. The plurality of semiconductor patterns 150 within the same layer may be disposed to be spaced apart along the first direction DR1. Each of the plurality of semiconductor patterns 150 may have a ring shape. For example, each of the plurality of semiconductor patterns 150 may have a circular ring shape, but is not limited thereto.

In an embodiment, the plurality of gate insulation layers Gox may be stacked in the third direction DR3. The first interlayer insulating layer 130 may be located between the plurality of gate insulation layers Gox stacked in the third direction DR3. However, the embodiment is not limited thereto. For example, a single the gate insulation layer Gox may cover an inner surface of the plurality of first interlayer insulating layers 130 and the plurality of semiconductor patterns 150 stacked in the third direction DR3 and extend in the third direction DR3. The plurality of gate insulation layers Gox within the same layer may be disposed to be spaced apart along the second direction DR2. The plurality of gate insulation layers Gox within the same layer may be disposed to be spaced apart along the first direction DR1. Each of the plurality of gate insulation layers Gox may have a ring shape. For example, each of the plurality of gate insulation layers Gox may have a circular ring shape, but is not limited thereto.

Referring to FIG. 29 and FIG. 30, the second sacrificial layer 136 located within each second hole H2 may be removed, and the plurality of first electrodes 161 and the plurality of first dielectric layers 162 may be formed within each second hole H2.

First, a photoresist pattern may be formed on an upper surface of an interlayer insulating layer located uppermost, and the second sacrificial layer 136 located within each second hole H2 may be etched by performing an etching process using the photoresist pattern. For example, the second sacrificial layer 136 may be etched by using a material having high etch selectivity with respect to the first interlayer insulating layer 130 and the second interlayer insulating layer 132. For example, the second insulation layer 122 may be used as an etch-stop layer. The etching process may be stopped when the upper surface of the second insulation layer 122 is exposed.

Thereafter, a part of the plurality of second interlayer insulating layers 132 exposed through the plurality of second holes H2 may be etched. For example, the second interlayer insulating layer 132 may be etched by using a material having etch selectivity with respect to the first interlayer insulating layer 130, the second insulation layer 122, and the sacrificial layers 134, 138, 140, and 142. Accordingly, the plurality of second interlayer insulating layers 132 may be recessed in a diameter direction of each second hole H2, to form a plurality of second recesses R2. The plurality of second recesses R2 may have the inner surface of the second interlayer insulating layer 132 and the external circumferential surface of the semiconductor pattern 150 as a bottom surface, and have upper surface and the lower surface of the plurality of first interlayer insulating layers 130 as both sidewalls.

Thereafter, the plurality of first electrodes 161 and the plurality of first dielectric layers 162 may be formed. The plurality of first electrodes 161 may be formed by depositing and patterning the first electrode material layer, and the plurality of first dielectric layers 162 may be formed by depositing and patterning a first dielectric material layer. For example, the first electrode material layer and the first dielectric material layer may be formed through an ALD process or a CVD process, but is not limited thereto.

The first electrode material layer may be formed not only in the interior of the second recess R2 in each second hole H2 but also on the side surface of the plurality of first interlayer insulating layers 130. Thereafter, a portion of the first electrode material layer located on the side surface of the plurality of first interlayer insulating layers 130 may be removed through an etch-back process. Accordingly, the first electrode material layer may be separated in the third direction DR3 so that the plurality of first electrodes 161 disposed spaced apart in the third direction DR3 may be formed.

The first dielectric material layer may be formed not only in the interior of the second recess R2 in each second hole H2 but also on the side surface of the plurality of first interlayer insulating layers 130. Thereafter, a portion of the first dielectric material layer located on the side surface of the plurality of first interlayer insulating layers 130 may be removed through an etch-back process. Accordingly, the first dielectric material layer may be separated in the third direction DR3, so that the plurality of first dielectric layers 162 disposed to be spaced apart in the third direction DR3 may be formed.

Each first electrode 161 and each first dielectric layer 162 may be located within each second recess R2. The first electrode 161 may cover the inner surface of the second interlayer insulating layer 132 and the external circumferential surface of the semiconductor pattern 150 within the second recess R2. In an embodiment, the first electrode 161 may be connected to the semiconductor pattern 150. For example, the first electrode 161 may be in contact with a part of the external circumferential surface of the semiconductor pattern 150 in the first direction DR1, but is not limited thereto. For example, another predetermined layer may be further located between the semiconductor pattern 150 and the first electrode 161. The first dielectric layer 162 may cover the inner surface of the first electrode 161 within the second recess R2.

The first electrode 161 may include a conductive material. The first electrode 161 may include, for example, at least one among a metallic material, a conductive metal nitride, and a doped semiconductor material. The first dielectric layer 162 may include at least one among a high-dielectric material, a ferroelectric material, or an antiferroelectric material.

Thereafter, a sixth sacrificial layer 144 may be formed within each second hole H2. For example, after depositing the sacrificial material layer filling the plurality of second holes H2, the sixth sacrificial layer 144 may be formed within each second hole H2, through a planarization process. The planarization process may be, e.g., a CMP process, but is not limited thereto.

The sixth sacrificial layer 144 may include an insulating material. The sixth sacrificial layer 144 may include a material having etch selectivity with respect to the first interlayer insulating layer 130, the second interlayer insulating layer 132, and the second insulation layer 122.

In an embodiment, the plurality of first electrodes 161 may be stacked in the third direction DR3. The first interlayer insulating layer 130 may be located between the plurality of first electrodes 161 stacked in the third direction DR3. The plurality of first electrodes 161 within the same layer may be disposed to be spaced apart along the second direction DR2. The plurality of first electrodes 161 within the same layer may be disposed to be spaced apart along the first direction DR1. Each of the plurality of first electrodes 161 may have a ring shape. For example, each of the plurality of first electrodes 161 may have a circular ring shape, but is not limited thereto.

In an embodiment, the plurality of first dielectric layers 162 may be stacked in the third direction DR3. The first interlayer insulating layer 130 may be located between the plurality of first dielectric layers 162 stacked in the third direction DR3. However, the embodiment is not limited thereto. For example, the single first dielectric layer 162 may cover an inner surface of the plurality of first interlayer insulating layers 130 and the plurality of first electrodes 161 stacked in the third direction DR3 and extend in the third direction DR3. The plurality of first dielectric layers 162 within the same layer may be disposed to be spaced apart along the second direction DR2. The plurality of first dielectric layers 162 within the same layer may be disposed to be spaced apart along the first direction DR1. Each of the plurality of first dielectric layers 162 may have a ring shape. For example, each of the plurality of first dielectric layers 162 may have a circular ring shape, but is not limited thereto.

Referring to FIG. 31 and FIG. 32, the third sacrificial layer 138 located within each third hole H3 may be removed, and the plurality of third electrodes 171 and the plurality of second dielectric layers 172 may be formed within each third hole H3.

First, a photoresist pattern may be formed on an upper surface of an interlayer insulating layer located uppermost, and the third sacrificial layer 138 located within each third hole H3 may be etched by performing an etching process using the photoresist pattern. For example, the third sacrificial layer 138 may be etched by using a material having high etch selectivity with respect to the first interlayer insulating layer 130 and the second interlayer insulating layer 132. For example, the second insulation layer 122 may be used as an etch-stop layer. The etching process may be stopped when the upper surface of the second insulation layer 122 is exposed.

Thereafter, a part of the plurality of second interlayer insulating layers 132 exposed through the plurality of third holes H3 may be etched. For example, the second interlayer insulating layer 132 may be etched by using a material having etch selectivity with respect to the first interlayer insulating layer 130, the second insulation layer 122, and the sacrificial layers 134, 140, 142, and 144. Accordingly, the plurality of second interlayer insulating layers 132 may be recessed in a diameter direction of each third hole H3, to form a plurality of third recesses R3. The plurality of third recesses R3 may have the inner surface of the second interlayer insulating layer 132 and the external circumferential surface of the first electrode 161 as a bottom surface, and have upper surface and the lower surface of the plurality of first interlayer insulating layers 130 as both sidewalls.

Thereafter, the plurality of third electrodes 171 and the plurality of second dielectric layers 172 may be formed. The plurality of third electrodes 171 may be formed by depositing and patterning the second electrode material layer, and the plurality of second dielectric layers 172 may be formed by depositing and patterning a second dielectric material layer. For example, the second electrode material layer and the second dielectric material layer may be formed through an ALD process or a CVD process, but are not limited thereto.

The second electrode material layer may be formed not only in the interior of the third recess R3 in each third hole H3 but also on the side surface of the plurality of first interlayer insulating layers 130. Thereafter, a portion of the second electrode material layer located on the side surface of the plurality of first interlayer insulating layers 130 may be removed through an etch-back process. Accordingly, the second electrode material layer may be separated in the third direction DR3 so that the plurality of third electrodes 171 disposed spaced apart in the third direction DR3 may be formed.

The second dielectric material layer may be formed not only in the interior of the third recess R3 in each third hole H3 but also on the side surface of the plurality of first interlayer insulating layers 130. Thereafter, a portion of the second dielectric material layer located on the side surface of the plurality of first interlayer insulating layers 130 may be removed through an etch-back process. Accordingly, the second dielectric material layer may be separated in the third direction DR3, so that the plurality of second dielectric layers 172 disposed to be spaced apart in the third direction DR3 may be formed.

Each the third electrode 171 and each second dielectric layer 172 may be located within each third recess R3. The third electrode 171 may cover the inner surface of the second interlayer insulating layer 132 and the external circumferential surface of the first electrode 161 within the third recess R3. In an embodiment, the third electrode 171 may be connected to the first electrode 161. For example, the third electrode 171 may be in contact with a part of the external circumferential surface of the first electrode 161 in the first direction DR1. For example, when the third electrode 171 and the first electrode 161 includes the same material, an interface between the third electrode 171 and the first electrode 161 may not be identified. The second dielectric layer 172 may cover the inner surface of the third electrode 171 within the third recess R3.

The third electrode 171 may include a conductive material. The third electrode 171 may include, for example, at least one among a metallic material, a conductive metal nitride, and a doped semiconductor material. The second dielectric layer 172 may include at least one among a high-dielectric material, a ferroelectric material, or an antiferroelectric material.

Thereafter, a seventh sacrificial layer 146 may be formed within each third hole H3. For example, after depositing the sacrificial material layer filling the plurality of third holes H3, the seventh sacrificial layer 146 may be formed within each third hole H3, through a planarization process. The planarization process may be, e.g., a CMP process, but is not limited thereto.

The seventh sacrificial layer 146 may include an insulating material. The seventh sacrificial layer 146 may include a material having etch selectivity with respect to the first interlayer insulating layer 130, the second interlayer insulating layer 132, and the second insulation layer 122.

In an embodiment, the plurality of third electrodes 171 may be stacked in the third direction DR3. The first interlayer insulating layer 130 may be located between the plurality of third electrodes 171 stacked in the third direction DR3. The plurality of third electrodes 171 within the same layer may be disposed to be spaced apart along the second direction DR2. The plurality of third electrodes 171 within the same layer may be disposed to be spaced apart along the first direction DR1. Each of the plurality of third electrodes 171 may have a ring shape. For example, each of the plurality of third electrodes 171 may have a circular ring shape, but is not limited thereto.

In an embodiment, the plurality of second dielectric layers 172 may be stacked in the third direction DR3. The first interlayer insulating layer 130 may be located between the plurality of second dielectric layers 172 stacked in the third direction DR3. However, the embodiment is not limited thereto. For example, the single second dielectric layer 172 may cover an inner surface of the plurality of first interlayer insulating layers 130 and the plurality of third electrodes 171 stacked in the third direction DR3 and extend in the third direction DR3. The plurality of second dielectric layers 172 within the same layer may be disposed to be spaced apart along the second direction DR2. The plurality of second dielectric layers 172 within the same layer may be disposed to be spaced apart along the first direction DR1. Each of the plurality of second dielectric layers 172 may have a ring shape. For example, each of the plurality of second dielectric layers 172 may have a circular ring shape, but is not limited thereto.

Referring to FIG. 33 and FIG. 34, the first sacrificial layer 134 located within the trench T1 may be removed, and the plurality of bit lines BL may be formed within the trench T1.

First, a photoresist pattern may be formed on an upper surface of an interlayer insulating layer located uppermost, and the first sacrificial layer 134 located within the trench T1 may be etched by performing an etching process using the photoresist pattern. For example, the first sacrificial layer 134 may be etched by using a material having high etch selectivity with respect to the first interlayer insulating layer 130 and the second interlayer insulating layer 132. For example, the second insulation layer 122 may be used as an etch-stop layer. The etching process may be stopped when the upper surface of the second insulation layer 122 is exposed.

Thereafter, a part of the plurality of second interlayer insulating layers 132 exposed through the trench T1 may be etched. For example, the second interlayer insulating layer 132 may be etched by using a material having etch selectivity with respect to the first interlayer insulating layer 130, the second insulation layer 122, and the sacrificial layers 140, 142, 144, and 146. Accordingly, the plurality of second interlayer insulating layers 132 may be recessed in the first direction DR1, to form a plurality of fourth recesses R4. The plurality of fourth recesses R4 may have the inner surface of the second interlayer insulating layer 132 and the external circumferential surface of the semiconductor pattern 150 as a bottom surface, and have upper surface and the lower surface of the plurality of first interlayer insulating layers 130 as both sidewalls.

Thereafter, the plurality of bit lines BL may be formed. The plurality of bit lines BL may be formed by depositing and patterning the bit line material layer. For example, the bit line material layer may be formed through an ALD process or a CVD process, but is not limited thereto.

The bit line material layer may be formed not only in the interior of the fourth recess R4 within the trench T1 but also on the side surface of the plurality of first interlayer insulating layers 130. Thereafter, a portion of the bit line material layer located on the side surface of the plurality of first interlayer insulating layers 130 may be removed through an etch-back process. Accordingly, the bit line material layer may be separated in the third direction DR3 so that the plurality of bit lines BL disposed spaced apart in the third direction DR3 may be formed.

Each bit line BL may be located within each fourth recess R4. The bit line BL may cover the inner surface of the second interlayer insulating layer 132 and the external circumferential surface of the semiconductor pattern 150 within the fourth recess R4. In an embodiment, the bit line BL may be connected to the semiconductor pattern 150. For example, the bit line BL may be in contact with a part of the external circumferential surface of the semiconductor pattern 150 in the first direction DR1, but is not limited thereto. For example, another predetermined layer may be further located between the bit line BL and the semiconductor pattern 150.

The bit line BL may include a conductive material. The bit line BL may include, for example, a doped semiconductor material, a conductive metal nitride, a metal, a metal-semiconductor compound, or a combination thereof, but is not limited thereto.

Thereafter, a third interlayer insulating layer 148 may be formed within the trench T1. For example, after depositing interlayer insulating layer filling the trench T1, interlayer insulating layer may be formed within each trench T1, through a planarization process. The planarization process may be, e.g., a CMP process, but is not limited thereto.

The third interlayer insulating layer 148 may include an insulating material. The third interlayer insulating layer 148 may include a material having etch selectivity with respect to the sacrificial layers 140, 142, 144, and 146.

In an embodiment, the plurality of bit lines BL may be stacked in the third direction DR3. The first interlayer insulating layer 130 may be located between the plurality of bit lines BL stacked in the third direction DR3. Each of the plurality of bit lines BL may extend along the second direction DR2. Each of the plurality of bit lines BL may have a rod shape. The plurality of bit lines BL within the same layer may be disposed to be spaced apart along the first direction DR1. The third interlayer insulating layer 148 may be located between the two bit lines BL adjacent in the first direction DR1. The two bit lines BL adjacent in the first direction DR1 may be spaced apart and insulated by the third interlayer insulating layer 148.

Referring to FIG. 35 and FIG. 36, the word line WL, the second electrode 163, and the fourth electrode 173 may be formed.

First, the fourth sacrificial layer 140, the sixth sacrificial layer 144, the seventh sacrificial layer 146, and the fifth sacrificial layer 142 located within each first hole H1, each second hole H2, each third hole H3, and each fourth hole H4 may be removed. For example, the fourth sacrificial layer 140, the fifth sacrificial layer 142, the sixth sacrificial layer 144, and the seventh sacrificial layer 146 may be etched by using a material having etch selectivity with respect to the first interlayer insulating layer 130, the second interlayer insulating layer 132, the third interlayer insulating layer 148, and the second insulation layer 122. For example, the second insulation layer 122 may be used as an etch-stop layer. The etching process may be stopped when the upper surface of the second insulation layer 122 is exposed.

Thereafter, the word line WL may be formed within each first hole H1 and each fourth hole H4, the second electrode 163 may be formed within each second hole H2 may be formed, and the fourth electrode 173 may be formed within each third hole H3. For example, after depositing the electrode material layer filling the plurality of first holes H1, the plurality of second holes H2, the plurality of third holes H3, and the plurality of fourth holes H4, through a planarization process, the word line WL may be formed within each first hole H1 and each fourth hole H4, the second electrode 163 may be formed within each second hole H2, and the fourth electrode 173 may be formed within each fourth hole H4.

The word line WL, the second electrode 163, and the fourth electrode 173 may include a conductive material. For example, each of the word line WL, the second electrode 163, and the fourth electrode 173 may include at least one among a metallic material, a conductive metal nitride, and a doped semiconductor material.

In an embodiment, the word line WL, the second electrode 163, and the fourth electrode 173 may include the same material, but are not limited thereto. For example, the word line WL may include a different material from the second electrode 163 and the fourth electrode 173. For example, the second electrode 163 and the fourth electrode 173 may include different materials.

In an embodiment, the word line WL, the second electrode 163, and the fourth electrode 173 may extend in the third direction DR3. The word line WL, the second electrode 163, and the fourth electrode 173 may have a pillar shape extending in the third direction DR3. For example, the word line WL, the second electrode 163, and the fourth electrode 173 may have a cylindrical shape, but are not limited thereto.

In an embodiment, the word line WL may penetrate the semiconductor pattern 150 and extend in the third direction DR3. The word line WL may be surrounded by the semiconductor pattern 150. A part of the external circumferential surface of the word line WL may be surrounded by the semiconductor pattern 150. The gate insulation layer Gox may be located between the word line WL and the semiconductor pattern 150. By the gate insulation layer Gox, the word line WL may be spaced apart from the semiconductor pattern 150. The word line WL may penetrate the plurality of semiconductor patterns 150 stacked in the third direction DR3 and extend in the third direction DR3. The word line WL may be surrounded by the plurality of semiconductor patterns 150 stacked in the third direction DR3.

In an embodiment, the second electrode 163 may penetrate the first electrode 161 and extend in the third direction DR3. The second electrode 163 may be surrounded by the first electrode 161. A part of the external circumferential surface of the second electrode 163 may be surrounded by the first electrode 161. The first dielectric layer 162 may be located between the second electrode 163 and the first electrode 161. By the first dielectric layer 162, the second electrode 163 may be spaced apart from the first electrode 161. The second electrode 163 may penetrate the first electrode 161 stacked in the third direction DR3 and extend in the third direction DR3. The second electrode 163 may be surrounded by the plurality of first electrodes 161 stacked in the third direction DR3.

In an embodiment, the fourth electrode 173 may penetrate the third electrode 171 and extend in the third direction DR3. The fourth electrode 173 may be surrounded by the third electrode 171. A part of the external circumferential surface of the fourth electrode 173 may be surrounded by the third electrode 171. The second dielectric layer 172 may be located between the fourth electrode 173 and the third electrode 171. By the second dielectric layer 172, the fourth electrode 173 may be spaced apart from the third electrode 171. The fourth electrode 173 may penetrate the third electrode 171 stacked in the third direction DR3 and extend in the third direction DR3. The fourth electrode 173 may be surrounded by the plurality of third electrodes 171 stacked in the third direction DR3.

In an embodiment, the first data storage portion 160 may include the first electrode 161, the second electrode 163 surrounded by the first electrode 161, and the first dielectric layer 162 located between the first electrode 161 and the second electrode 163. The first electrode 161 may be connected to the semiconductor pattern 150. In an embodiment, the second data storage portion 170 may include the third electrode 171 connected to the first electrode 161, the fourth electrode 173 surrounded by the third electrode 171, and the second dielectric layer 172 located between the third electrode 171 and the fourth electrode 173.

A semiconductor device according to an embodiment may include the plurality of memory cells, and each of the plurality of memory cells may include the semiconductor pattern 150, the bit line BL connected to the semiconductor pattern 150, the word line WL adjacent to the semiconductor pattern 150, the first data storage portion 160 connected to the semiconductor pattern 150, and the second data storage portion 170 connected to the first data storage portion 160. The plurality of memory cells may be stacked in the third direction DR3 perpendicular to the upper surface of the substrate 110. The plurality of memory cells disposed spaced apart in the second direction DR2 parallel to the upper surface of the substrate 110 within the same layer. The plurality of memory cells may be disposed to be spaced apart in the first direction DR1 parallel to the upper surface of the substrate 110 and intersecting (e.g., orthogonal to) the second direction DR2. Two memory cells adjacent in the first direction DR1 may be located on both sides of the third interlayer insulating layer 148. Two memory cells adjacent in the first direction DR1 may have a symmetry structure based on the third interlayer insulating layer 148.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device, comprising:
a substrate;
a bit line and a word line that extend in directions intersecting each other on the substrate;
a semiconductor pattern connected to the bit line and adjacent to the word line; and
a first data storage portion connected to the semiconductor pattern and a second data storage portion connected to the first data storage portion,
wherein the first data storage portion comprises:
a first electrode connected to the semiconductor pattern;
a second electrode surrounded by the first electrode; and
a first dielectric layer disposed between the first electrode and the second electrode, and
the second data storage portion comprise:
a third electrode connected to the first electrode;
a fourth electrode surrounded by the third electrode; and
a second dielectric layer disposed between the third electrode and the fourth electrode.

2. The semiconductor device of claim 1, wherein the second electrode and the fourth electrode extend in a direction perpendicular to an upper surface of the substrate.

3. The semiconductor device of claim 1, further comprising a plurality of first interlayer insulating layers,
wherein the plurality of first interlayer insulating layers include a first interlayer insulating layer disposed on an upper surface of the first electrode and an upper surface of the third electrode, and a first interlayer insulating layer disposed on a lower surface of the first electrode and a lower surface of the third electrode,
wherein, on a cross-section according to a direction parallel to the bit line and a direction parallel to the word line:
the second electrode extends on an inner surface of the first electrode and inner surfaces of the plurality of first interlayer insulating layers; and
the fourth electrode extends on an inner surface of the third electrode and another inner surface of the plurality of first interlayer insulating layers.

4. The semiconductor device of claim 3, wherein, on the cross-section according to the direction parallel to the bit line and the direction parallel to the word line:
the second electrode is further disposed between the plurality of first interlayer insulating layers disposed on both sides of the first electrode; and
the fourth electrode is further disposed between the plurality of first interlayer insulating layers disposed on both sides of the third electrode.

5. The semiconductor device of claim 3, wherein, on the cross-section according to the direction parallel to the bit line and the direction parallel to the word line, each of the first electrode and the third electrode comprises:
a vertical portion extending in the direction perpendicular to the upper surface of the substrate between two first interlayer insulating layers adjacent in a direction perpendicular to an upper surface of the substrate; and
two horizontal portions that extend from both end portions of the vertical portion in a direction parallel to the upper surface of the substrate.

6. The semiconductor device of claim 5, wherein, on the cross-section according to the direction parallel to the bit line and the direction parallel to the word line:
the second electrode is further disposed between the two horizontal portions of the first electrode; and
the fourth electrode is further disposed between the two horizontal portions of the third electrode.

7. The semiconductor device of claim 5, wherein, on the cross-section according to the direction parallel to the bit line and the direction parallel to the word line:
the second electrode is further disposed on an upper surface and a lower surface of each of two horizontal portions of the first electrode;
the fourth electrode is further disposed on an upper surface and a lower surface of each of two horizontal portions of the third electrode.

8. The semiconductor device of claim 1, wherein the semiconductor pattern surrounds the word line.

9. The semiconductor device of claim 1, wherein the word line surrounds the semiconductor pattern.

10. The semiconductor device of claim 1, wherein the word line is disposed on at least first side among both sides of the semiconductor pattern.

11. The semiconductor device of claim 1, wherein:
one of the bit line and the word line extends in a direction perpendicular to an upper surface of the substrate.

12. The semiconductor device of claim 1, comprising a third data storage portion connected to the second data storage portion,
wherein the third data storage portion comprises:
a fifth electrode connected to the third electrode;
a sixth electrode surrounded by the fifth electrode; and
a third dielectric layer disposed between the fifth electrode and the sixth electrode.

13. The semiconductor device of claim 1, wherein each of the first dielectric layer and the second dielectric layer comprise at least one among a high-dielectric material, a ferroelectric material, or an antiferroelectric material.

14. The semiconductor device of claim 13, wherein:
two different material layers are alternately stacked in each of the first dielectric layer and the second dielectric layer; and
each of the two different material layers comprises a high-dielectric material, a ferroelectric material, or an antiferroelectric material.

15. The semiconductor device of claim 13, further comprising a semiconductor layer between the first electrode and the second electrode, and between the third electrode and the fourth electrode.

16. The semiconductor device of claim 1, wherein:
the first electrode and the second electrode comprise materials having different work functions; and
the third electrode and the fourth electrode comprise materials having different work functions.

17. The semiconductor device of claim 1, wherein a voltage is configured to be independently applied to the second electrode and the fourth electrode.

18. The semiconductor device of claim 1, wherein the first data storage portion and the second data storage portion are configured to store different information.

19. A semiconductor device, comprising:
a substrate;
a bit line and a word line that extend in directions intersecting each other on the substrate;
a semiconductor pattern connected to the bit line and adjacent to the word line; and
a first data storage portion connected to the semiconductor pattern and a second data storage portion connected to the first data storage portion,
wherein the first data storage portion comprise:
a first electrode connected to the semiconductor pattern;
a second electrode penetrating the first electrode and extending in a direction perpendicular to an upper surface of the substrate; and
a first dielectric layer disposed between the first electrode and the second electrode, and
the second data storage portion comprises:
a third electrode connected to the first electrode;
a fourth electrode penetrating the third electrode and extending in the direction perpendicular to the upper surface of the substrate; and
a second dielectric layer disposed between the third electrode and the fourth electrode.

20. A semiconductor device, comprising:
a substrate;
a bit line and a word line that extend in directions intersecting each other on the substrate;
a semiconductor pattern connected to the bit line and adjacent to the word line; and
a plurality of data storage portions connected to the semiconductor pattern,
wherein each of the plurality of data storage portions comprises:
a first electrode connected to the semiconductor pattern;
a second electrode surrounded by the first electrode; and
a dielectric layer disposed between the first electrode and the second electrode, and
the first electrodes of respective ones of the plurality of data storage portions are connected.
